(19) United States
(12) Patent Application Publication
(10) Pub. No.: US 2026/0090403 A1
(43) Pub. Date: Mar. 26, 2026

(54) SEMICONDUCTOR DEVICE AND VEHICLE

(71) Applicant: Rohm Co., Ltd., Kyoto-shi (JP)

(72) Inventors: Ryotaro KAKIZAKI, Kyoto-shi (JP); Koshun SAITO, Kyoto-shi (JP)

(21) Appl. No.: 19/403,353

(22) Filed: Nov. 28, 2025

Related U.S. Application Data
(63) Continuation of application No. PCT/JP2024/016981, filed on May 7, 2024.

(30) Foreign Application Priority Data
Jun. 5, 2023 (JP) 2023-092158

(51) Int. Cl. H01L 23/495; H01L 23/00; H01L 23/31

(52) U.S. Cl. CPC H10W 70/429; H10W 70/474; H10W 72/868; H10W 74/114; H10W 90/756; H10W 90/766

(57) ABSTRACT

A semiconductor device includes a semiconductor element, a first lead, and a sealing resin. The first lead includes a die pad portion including a first lead reverse surface, and a first terminal portion. The sealing resin includes a second resin surface facing in a z direction and a third resin surface facing in an x direction. The first lead includes a metal layer. The first lead reverse surface is exposed from the second resin surface. The first terminal portion includes a first-terminal base portion and a first-terminal tip portion. The first-terminal base portion passes through the third resin surface, and is spaced apart from a first resin surface in the z direction. The first-terminal tip portion is located below the first-terminal base portion. The first-terminal tip portion includes a tip surface exposed from the metal layer, and a recessed surface covered with the metal layer.

### TECHNICAL FIELD

The present disclosure relates to a semiconductor device and a vehicle

### BACKGROUND ART

JP-A-2017-174951 discloses an example of a semiconductor device. The semiconductor device in JP-A-2017-174951 includes: a first lead including a first pad having a pad obverse surface and a pad reverse surface; a second lead; a third lead; a semiconductor element mounted on the pad obverse surface; and a sealing resin in contact with the pad obverse surface and covering the semiconductor element. The first lead, the second lead, and the third lead have a first terminal, a second terminal, and a third terminal, respectively, that extend in the same direction. The first terminal, the second terminal, and the third terminal are inserted into through-holes of a circuit board or the like, whereby the semiconductor device is mounted on the circuit board. In the case where the semiconductor device is attached to a heat sink, an insulating sheet may be provided between the pad reverse surface and the heat sink.

### BRIEF DESCRIPTION OF THE DRAWINGS

FIG. 1 is a perspective view showing a semiconductor device according to a first embodiment

FIG. 2 is a perspective view corresponding to FIG. 1, in which a sealing resin is indicated with imaginary lines and a plurality of connecting members are omitted.

FIG. 3 is a perspective view showing the semiconductor device according to the first embodiment.

FIG. 4 is a perspective view corresponding to FIG. 3, in which the sealing resin is indicated with imaginary lines.

FIG. 5 is a perspective view showing the semiconductor device according to the first embodiment.

FIG. 6 is a plan view showing the semiconductor device according to the first embodiment.

FIG. 7 is a plan view corresponding to FIG. 6, in which the sealing resin is indicated with imaginary lines.

FIG. 8 is a bottom view showing the semiconductor device according to the first embodiment.

FIG. 9 is a bottom view corresponding to FIG. 8, in which the sealing resin is indicated with imaginary lines.

FIG. 10 is a front view showing the semiconductor device according to the first embodiment.

FIG. 11 is a right-side view showing the semiconductor device according to the first embodiment.

FIG. 12 is a cross-sectional view along line XII-XII in FIG. 9.

FIG. 13 is a cross-sectional view along line XIII-XIII in FIG. 9.

FIG. 14 is a cross-sectional view along line XIV-XIV in FIG. 9.

FIG. 15 is a cross-sectional view along line XV-XV in FIG. 9.

FIG. 16 is a partially enlarged perspective view showing a part (first-terminal tip portion) of FIG. 5.

FIG. 17 is a partially enlarged bottom view showing a part (first-terminal tip portion) of FIG. 8.

FIG. 18 is a partially enlarged front view showing a part (first-terminal tip portion) of FIG. 10.

FIG. 19 is a cross-sectional view showing the semiconductor device in use according to the first embodiment.

FIG. 20 is a schematic view showing a vehicle equipped with the semiconductor device according to the first embodiment.

FIG. 21 is a bottom view showing a step of a method for manufacturing the semiconductor device according to the first embodiment.

FIG. 22 is a perspective view corresponding to FIG. 3, and shows a semiconductor device according to a second embodiment.

FIG. 23 is a partially enlarged perspective view corresponding to FIG. 16, and shows a part (first-terminal tip portion) of FIG. 22.

FIG. 24 is a partial bottom view corresponding to FIG. 17, and shows the semiconductor device according to the second embodiment.

FIG. 25 is a partial front view corresponding to FIG. 18, and shows the semiconductor device according to the second embodiment.

FIG. 26 is a perspective view corresponding to FIG. 3, and shows a semiconductor device according to a third embodiment.

FIG. 27 is a partially enlarged perspective view corresponding to FIG. 16, and shows a part (first-terminal tip portion) of FIG. 26.

FIG. 28 is a partial bottom view corresponding to FIG. 17, and shows the semiconductor device according to the third embodiment.

FIG. 29 is a partial front view corresponding to FIG. 18, and shows the semiconductor device according to the third embodiment.

FIG. 30 is a perspective view corresponding to FIG. 3, and shows a semiconductor device according to a fourth embodiment.

FIG. 31 is a partially enlarged perspective view corresponding to FIG. 16, and shows a part (first-terminal tip portion) of FIG. 30.

FIG. 32 is a partial bottom view corresponding to FIG. 17, and shows the semiconductor device according to the fourth embodiment.

FIG. 33 is a partial front view corresponding to FIG. 18, and shows the semiconductor device according to the fourth embodiment.

FIG. 34 is a perspective view corresponding to FIG. 5, and shows a semiconductor device according to a fifth embodiment.

FIG. 35 is a perspective view corresponding to FIG. 5, and shows a semiconductor device according to a variation of the fifth embodiment.

FIG. 36 is a plan view showing a semiconductor device according to a first variation, with a sealing resin indicated with imaginary lines.

FIG. 37 is a plan view showing a semiconductor device according to a second variation, with a sealing resin indicated with imaginary lines.

FIG. 38 is a bottom view corresponding to FIG. 21, and shows a step of a method for manufacturing the semiconductor device in FIG. 37.

FIG. 39 is a perspective view corresponding to FIG. 5, and shows a semiconductor device according to a third variation.

FIG. 40 is a perspective view corresponding to FIG. 3, and shows the semiconductor device according to the third variation.

FIG. 41 is a perspective view corresponding to FIG. 5, and shows a semiconductor device according to a fourth variation.

FIG. 42 is a right-side view corresponding to FIG. 11, and shows a semiconductor device according to a fifth variation.

### DETAILED DESCRIPTION OF EMBODIMENTS

The following describes preferred embodiments of a semiconductor device according to the present disclosure in detail with reference to the drawings. In the following description, identical or similar elements are denoted by the same reference numerals and redundant descriptions of such elements are omitted. The terms such as "first", "second" and "third" in the present disclosure are used merely as labels and not intended to impose orders on the elements accompanied with these terms.

In the present disclosure, the phrases "an object A is formed in an object B" and "an object A is formed on an object B" include, unless otherwise specified, "an object A is formed directly in/on an object B" and "an object A is formed in/on an object B with another object interposed between the object A and the object B". Similarly, the phrases "an object A is disposed in an object B" and "an object A is disposed on an object B" include, unless otherwise specified, "an object A is disposed directly in/on an object B" and "an object A is disposed in/on an object B with another object interposed between the object A and the object B". Similarly, the phrase "an object A is located on an object B" includes, unless otherwise specified, "an object A is located on an object B in contact with the object B" and "an object A is located on an object B with another object interposed between the object A and the object B". Further, the phrase "an object A overlaps with an object B as viewed in a certain direction" includes, unless otherwise specified, "an object A overlaps with the entirety of an object B" and "an object A overlaps with a part of an object B". The phrase "an object A (or the material thereof) contains a material C" includes "an object A (or the material thereof) is made of a material C" and "an object A (or the material thereof) is mainly composed of a material C". Further, the phrase "a surface A faces (a first side or a second side) in a direction B", unless otherwise specified, is not limited to the case where the angle of the surface A with respect to the direction B is 90°, but also includes the case where the surface A is inclined to the direction B. The phrase "a surface A is perpendicular to a surface B" is not limited to the case where the angle of the surface A with respect to the surface B is exactly 90°, but also includes the case where the surface A is substantially perpendicular to the surface B.

### FIRST EMBODIMENT:

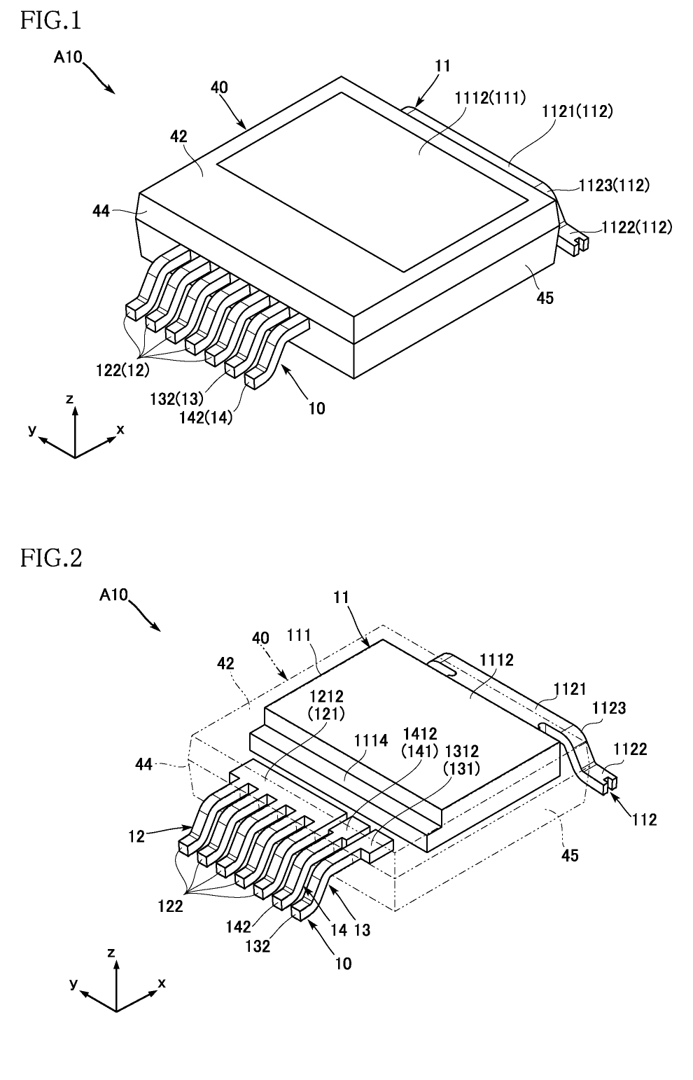

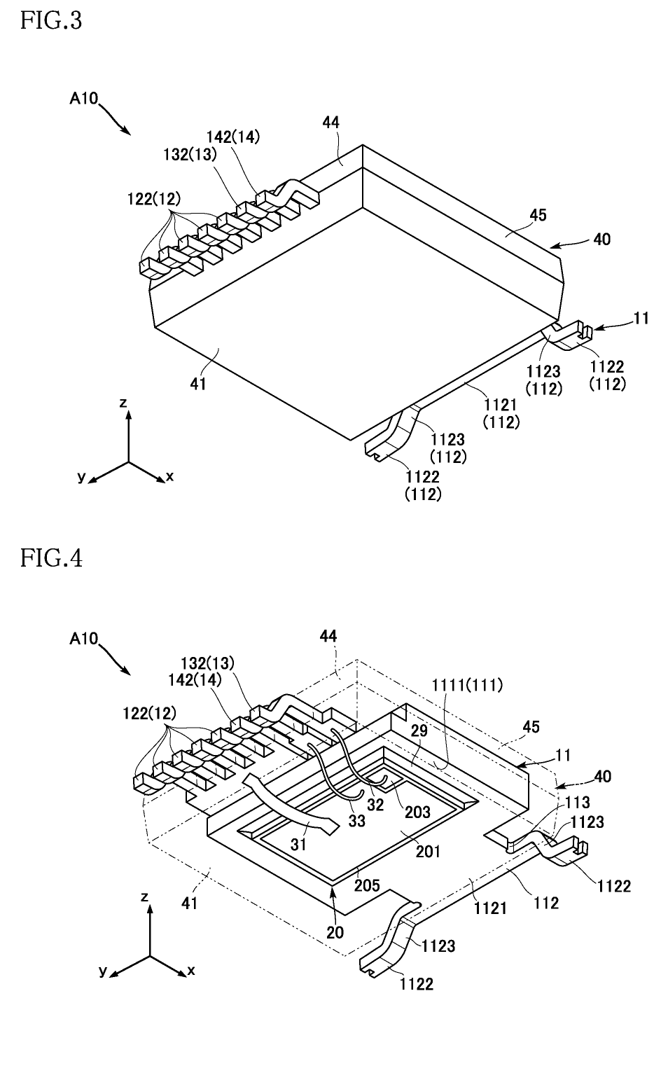

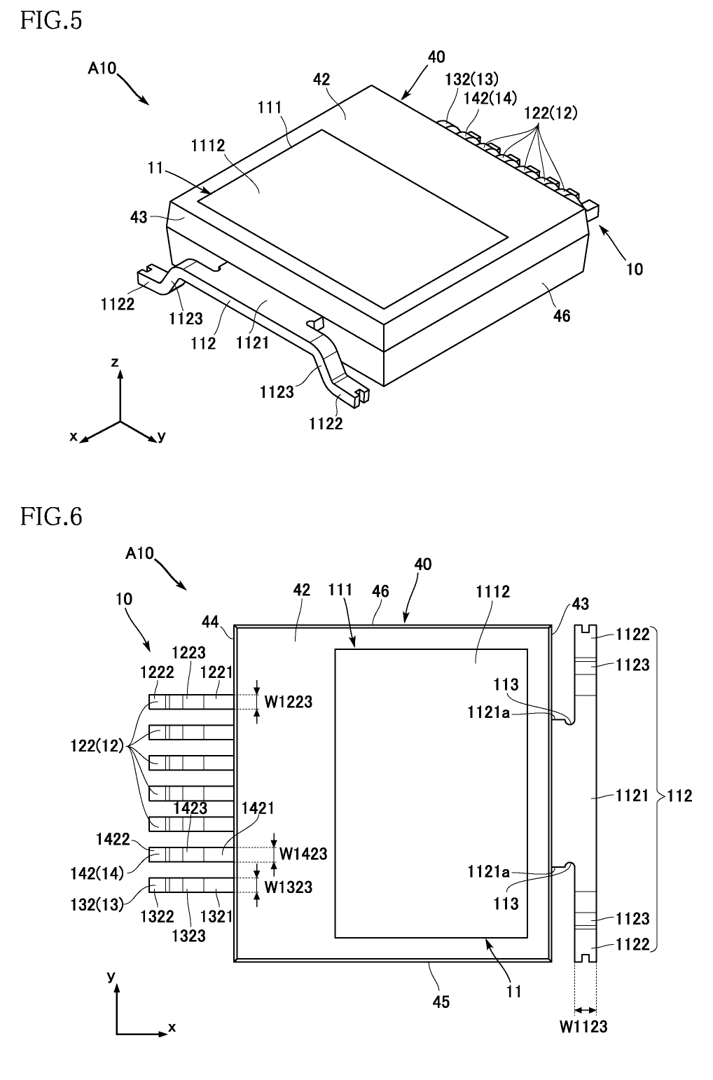

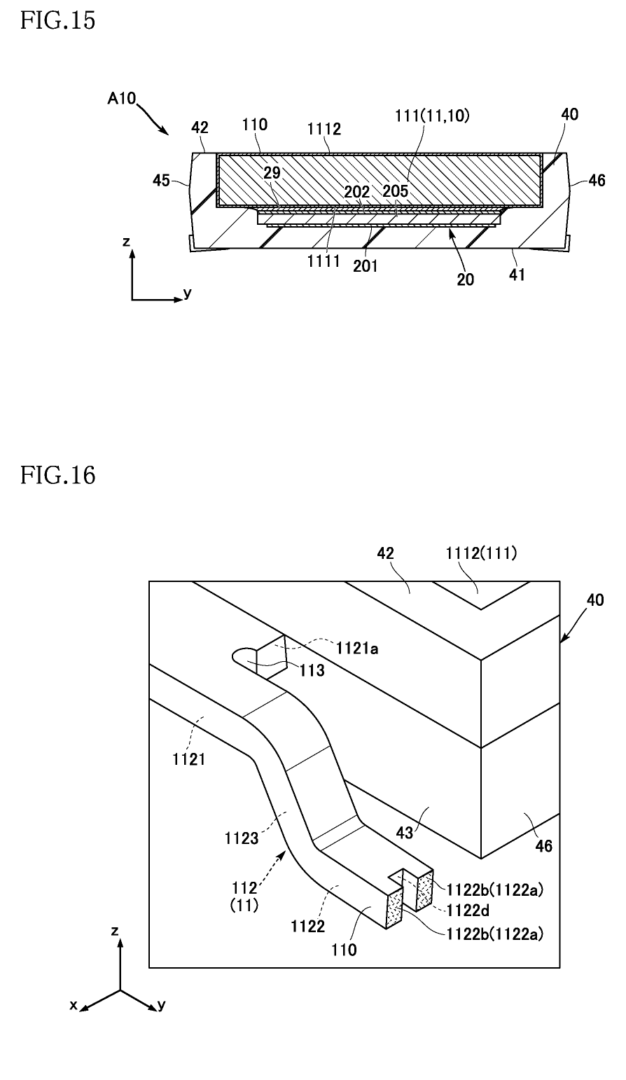

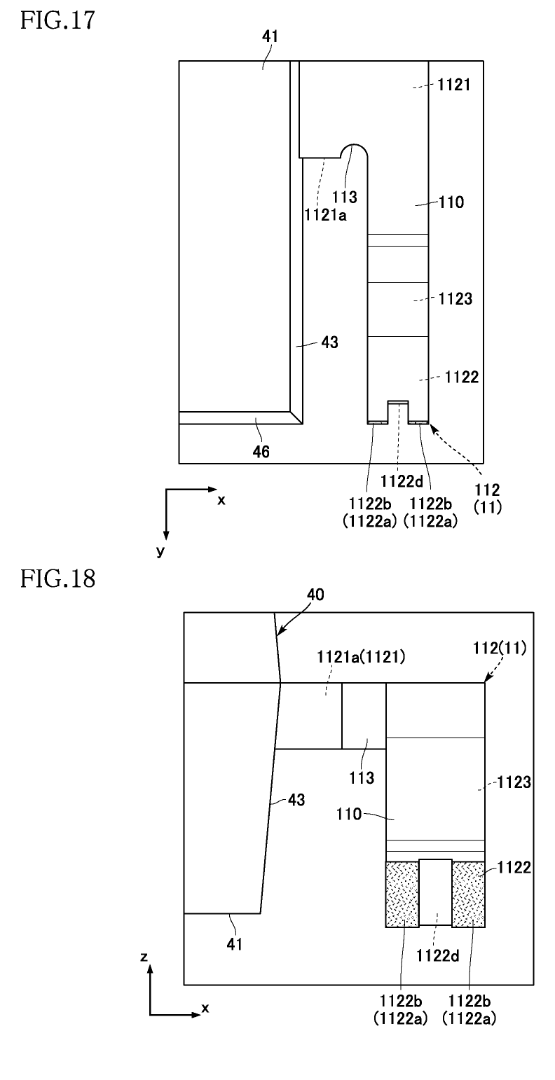

FIGS. 1 to 18 show a semiconductor device A10 according to a first embodiment. The semiconductor device A10 includes a conductive member 10, a semiconductor element 20, a plurality of connecting members 31, 32, and 33, and a sealing resin 40.

For convenience, the thickness direction of the semiconductor device A10 may be referred to as "thickness direction z". In the description below, one side in the thickness direction z may be referred to as "downward", and the other side as "upward". The terms such as "top", "bottom", "upward", "downward", "upper surface", and "lower surface" are used to indicate the relative positions of elements and components in the thickness direction z and do not necessarily define the relationship with respect to the direction of gravity. A direction perpendicular to the thickness direction z is referred to as "first direction x". The direction perpendicular to the thickness direction z and the first direction x is referred to as "second direction y".

The conductive member 10 constitutes a conduction path to the semiconductor element 20. The conductive member 10 of the present embodiment includes a first lead 11, a second lead 12, a third lead 13, and a fourth lead 14. The material of the first lead 11, the second lead 12, the third lead 13, and the fourth lead 14 is not particularly limited, and may contain copper (Cu) or a copper alloy. Plating, such as silver (Ag), nickel (Ni), or tin (Sn) plating, is applied to appropriate parts of the first lead 11, the second lead 12, the third lead 13, and the fourth lead 14. The plating corresponds to each of the metal layers 110, 120, 130, and 140 described below. In FIGS. 1 to 11, the plating (the metal layers 110, 120, 130, and 140 described below) is omitted.

As shown in FIGS. 1 to 18, the first lead 11 includes a metal layer 110, a die pad portion 111, and a first terminal portion 112.

The metal layer 110 covers a part of the first lead 11. As described above, the metal layer 110 is a plating layer made of silver (Ag), nickel (Ni), tin (Sn), etc. The material of the metal layer 110 is not limited to these, but it is desirable to use a material that provides a higher bonding strength with the bonding layer 29 described below than the material (e.g., Cu) of the first lead 11.

The die pad portion 111 has a first lead obverse surface 1111 and a first lead reverse surface 1112. The first lead obverse surface 1111 faces a first side (downward) in the thickness direction z. The first lead reverse surface 1112 faces a second side (upward) in the thickness direction z. The semiconductor element 20 is mounted on the first lead obverse surface 1111.

The die pad portion 111 of the present embodiment further includes a first lead side surface 1113 and a first intermediate surface 1114. The first lead side surface 1113 is located between the first lead obverse surface 1111 and the first lead reverse surface 1112 in the thickness direction z, and faces a first side in the first direction x. The first intermediate surface 1114 is located between the first lead obverse surface 1111 and the first lead reverse surface 1112 in the thickness direction z, and faces downward in the thickness direction z (the same side as the first lead obverse surface 1111).

The shape of the die pad portion 111 is not particularly limited. In the illustrated example, the die pad portion 111 has a rectangular shape as viewed in the thickness direction z. The shape of each of the first lead obverse surface 1111 and the first lead reverse surface 1112 is not particularly limited, and in the illustrated example, is rectangular as viewed in the thickness direction z.

In the present embodiment, the die pad portion 111 is entirely covered with the metal layer 110, as shown in FIG. 12. The metal layer 110 may not be formed in the area where the semiconductor element 20 is bonded (the area in contact with the bonding layer 29 described below), or may be made of a material different from that of the other areas.

The first terminal portion 112 is connected to the die pad portion 111. A large part of the first terminal portion 112 is exposed from the sealing resin 40. The first terminal portion 112 protrudes to a first side in the first direction x with respect to the sealing resin 40. The first terminal portion 112 is bent into a gull-wing shape. The first terminal portion 112 has a first-terminal base portion 1121, two first-terminal tip portions 1122, and two first-terminal intermediate portions 1123.

The first-terminal base portion 1121 is connected to the die pad portion 111, extends from the die pad portion 111 to the first side in the first direction x, and is parallel to the plane (x-y plane) perpendicular to the thickness direction z in the illustrated example. In the present embodiment, the thickness (the dimension in the thickness direction z) of the die pad portion 111 is larger than the thickness (the dimension in the thickness direction z) of the first-terminal base portion 1121. The first terminal portion 112 of the present embodiment has a single first-terminal base portion 1121. The shape of the first-terminal base portion 1121 is not particularly limited, and in the illustrated example, it is rectangular as viewed in the thickness direction z. The first-terminal base portion 1121 is spaced apart from the first lead reverse surface 1112 in the thickness direction z. In the illustrated example, the first-terminal base portion 1121 is in contact with the first lead obverse surface 1111. The lower surface (the surface facing downward in the thickness direction z) of the first-terminal base portion 1121 is flush with the first lead obverse surface 1111.

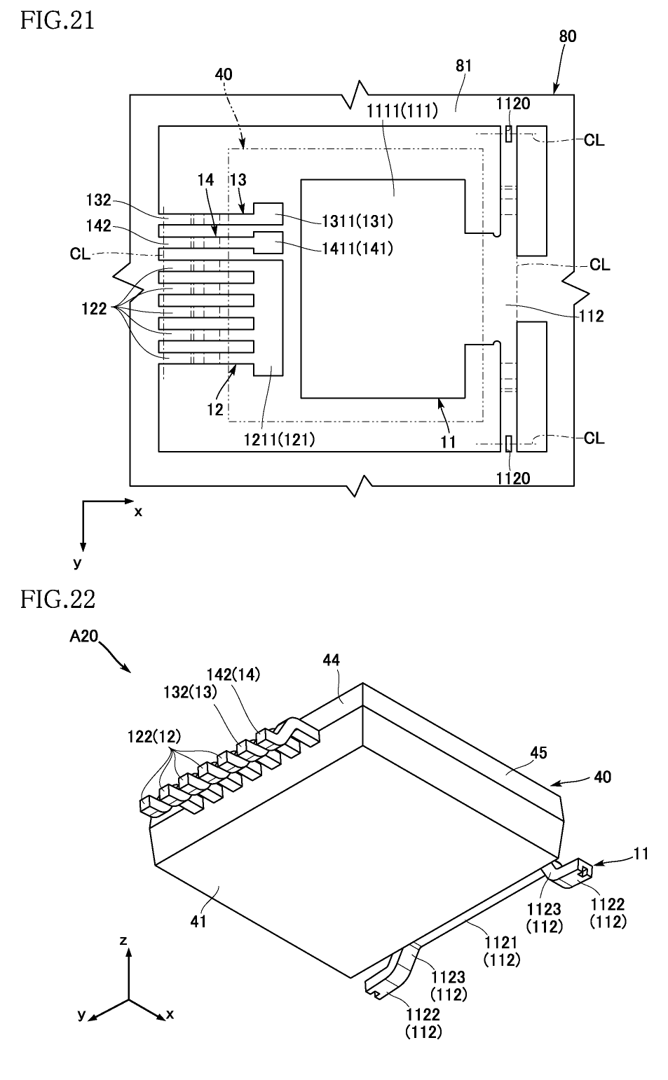

A part of the surface of the first-terminal base portion 1121 that faces the first side in the first direction x is exposed from the metal layer 110. The part of the first-terminal base portion 1121 described above corresponds to the part connected to the frame body 81 (see FIG. 21) of the lead frame 80 described below.

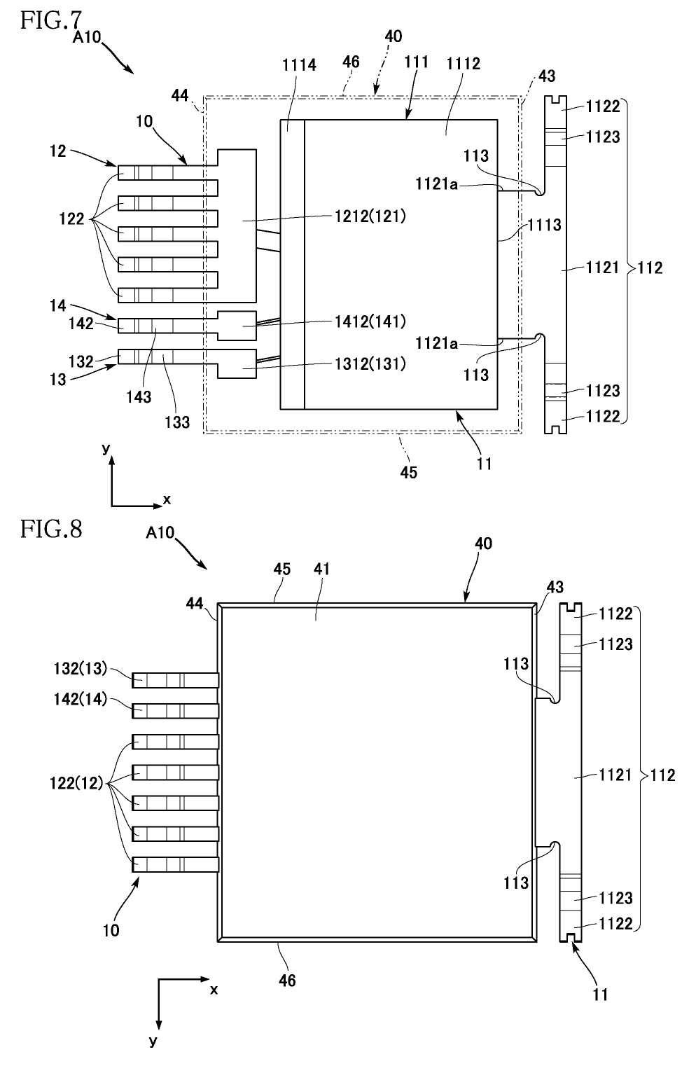

As shown in FIGS. 6 and 7, the first-terminal base portion 1121 has a pair of base side surfaces 1121a. The pair of base side surfaces 1121a are spaced apart from each other in the second direction y, and face away from each other in the second direction y. The pair of base side surfaces 1121a are parallel to the plane (x-z plane) perpendicular to the second direction y. The pair of base side surfaces 1121a may be slightly inclined to the x-z plane, or may be curved. Each of the base side surfaces 1121a is formed with a depression 113. In other words, the first lead 11 has a pair of depressions 113. In the semiconductor device A10, the pair of depressions 113 are recessed from the respective base side surfaces 1121a in the second direction y. In a configuration different from that of the semiconductor device A10, the depressions 113 may not be formed in the first terminal portion 112.

The two first-terminal tip portions 1122 are located downward in the thickness direction z with respect to the first-terminal base portion 1121. The two first-terminal tip portions 1122 are used to surface-mount the semiconductor device A10 on a circuit board or the like.

As shown in FIGS. 16 to 18, each of the two first-terminal tip portions 1122 has a first tip surface 1122a and a recessed surface 1122d. Unless otherwise specified, the following description of the first tip surface 1122a and the recessed surface 1122d applies to each first-terminal tip portion 1122. For convenience, FIGS. 16 to 18 depict the first tip surface 1122a with dots.

The first tip surface 1122a of each first-terminal tip portion 1122 is the end surface opposite to the end connected to the first-terminal intermediate portion 1123, namely the end surface farther from the first-terminal base portion 1121. The first tip surface 1122a is exposed from the metal layer 110. The first tip surface 1122a includes two exposed areas 1122b.

The two exposed areas 1122b are spaced apart from each other in the first direction x. Each of the two exposed areas 1122b is connected to the upper surface (the surface facing upward in the thickness direction z) of the first-terminal tip portion 1122 and the lower surface (the surface facing downward in the thickness direction z) of the first-terminal tip portion 1122.

The recessed surface 1122d is connected to the first tip surface 1122a. The recessed surface 1122d is flanked by the two exposed areas 1122b. In the present embodiment, the recessed surface 1122d is connected to the upper surface (the surface facing upward in the thickness direction z) of the first-terminal tip portion 1122 and the lower surface (the surface facing downward in the thickness direction z) of the first-terminal tip portion 1122. The recessed surface 1122d is recessed from the two exposed areas 1122b in the second direction y. The recessed surface 1122d has a side wall connected to one of the two exposed areas 1122b, a side wall connected to the other one of the two exposed areas 1122b, and a bottom portion connected to the two side walls. In the present embodiment, the bottom portion is flat. Alternatively, the bottom portion may be curved. In the present embodiment, the side walls are flat. Alternatively, they may be curved or may be inclined to the plane (y-z plane) perpendicular to the first direction x. The recessed surface 1122d is covered with the metal layer 110.

Each of the two first-terminal intermediate portions 1123 is provided between the first-terminal base portion 1121 and one of the two first-terminal tip portions 1122. Each of the first-terminal intermediate portions 1123 extends downward in the thickness direction z from the first-terminal base portion 1121. In the illustrated example, each of the first-terminal intermediate portions 1123 is inclined to the thickness direction z so that it extends outward from the first-terminal base portion 1121 in the second direction y. Unlike this example, the first-terminal intermediate portions 1123 may be parallel to the thickness direction z. As such, the dimension of the semiconductor device A10 can be reduced in the second direction y. On the other hand, the configuration in which the first-terminal intermediate portions 1123 are inclined to the thickness direction z facilitates manufacturing of the semiconductor device A10 (e.g., bending of the first terminal portion 112). The shape of each first-terminal intermediate portion 1123 is not particularly limited.

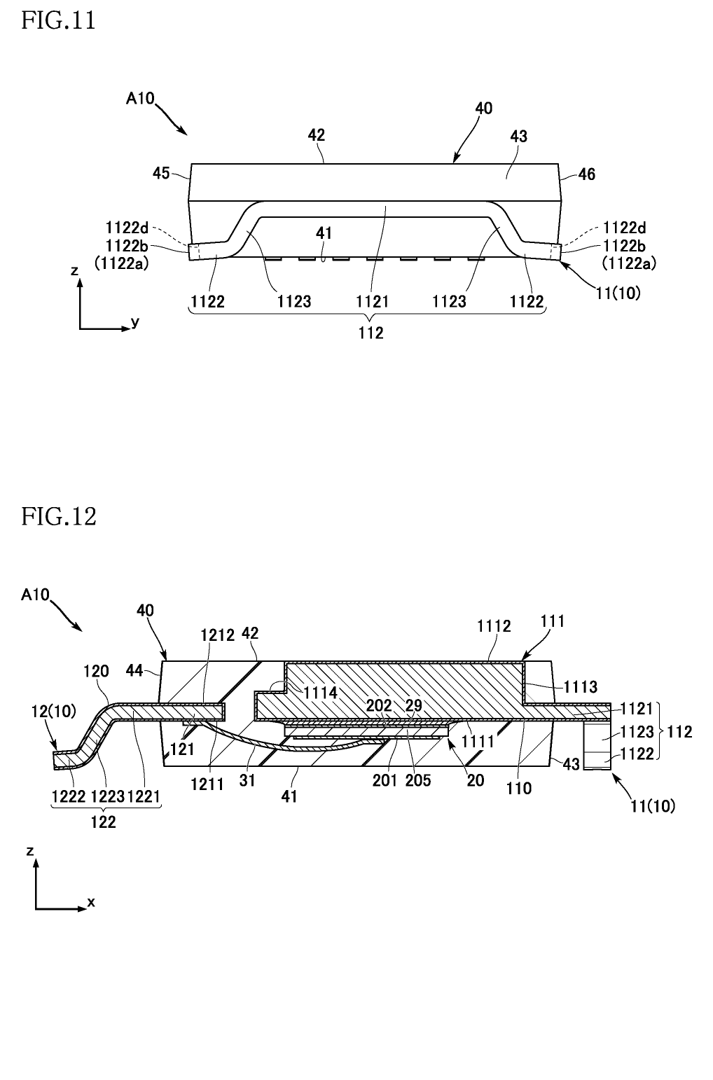

In the present embodiment, the two first-terminal tip portions 1122 extend outward from the two respective first-terminal intermediate portions 1123 in the second direction y. The two first-terminal tip portions 1122 are parallel to the second direction y. In the illustrated example, the two first-terminal tip portions 1122 and the two first-terminal intermediate portions 1123 are located at the same position in the first direction x. In the illustrated example, the two first-terminal tip portions 1122 are inclined to the x-y plane, as shown in FIG. 11. Unlike this example, the two first-terminal tip portions 1122 may be parallel to the x-y plane.

The first terminal portion 112 is covered with the metal layer 110, except for the two exposed areas 1122b of each first tip surface 1122a. In other words, the two exposed areas 1122b of each first tip surface 1122a in the first terminal portion 112 are exposed from the metal layer 110. The recessed surfaces 1122d are covered with the metal layer 110.

The second lead 12 is spaced apart from the first lead 11 (the die pad portion 111) to a second side in the first direction x. The second lead 12 includes a metal layer 120, a pad portion 121, and a plurality of second terminal portions 122.

The metal layer 120 covers a part of the second lead 12. As described above, the metal layer 120 may be a plating layer of Ag, Ni, or Sn. The material of the metal layer 120 is not limited to these.

The pad portion 121 has a second lead obverse surface 1211 and a second lead reverse surface 1212. The second lead obverse surface 1211 faces downward (the first side) in the thickness direction z. The second lead reverse surface 1212 faces upward (the second side) in the thickness direction z. The second lead obverse surface 1211 is connected to a connecting member 31. The shape of the pad portion 121 is not particularly limited, and in the illustrated example, it has a rectangular shape elongated in the second direction y. As viewed in the thickness direction z, the pad portion 121 is smaller than the die pad portion 111. The dimension of the pad portion 121 in the thickness direction z is smaller than the dimension of the die pad portion 111 in the thickness direction z, and is the same as the dimension of the first terminal portion 112 in the thickness direction z. In the illustrated example, the second lead obverse surface 1211 is located at the same position as the first lead obverse surface 1111 of the die pad portion 111 in the thickness direction z.

The second terminal portions 122 are connected to the pad portion 121. A large part of each second terminal portion 122 is exposed from the sealing resin 40. The second terminal portions 122 protrude to the second side in the first direction x with respect to the sealing resin 40. Thus, the second terminal portions 122 are disposed on the side opposite to the first terminal portion 112 in the first direction x with the sealing resin 40 interposed therebetween. The second terminal portions 122 are arranged side by side in the second direction y. Each of the second terminal portions 122 is bent into a gull-wing shape. As can be understood from FIG. 12, each of the second terminal portions 122 has a second-terminal base portion 1221, a second-terminal tip portion 1222, and a second-terminal intermediate portion 1223. Unless otherwise specified, the following description of the second-terminal base portion 1221, the second-terminal tip portion 1222, and the second-terminal intermediate portion 1223 applies to each second terminal portion 122.

The second-terminal base portion 1221 is connected to the pad portion 121, extends from the pad portion 121 to the second side in the first direction x, and is parallel to the x-y plane in the illustrated example. The shape of the second-terminal base portion 1221 is not particularly limited, and in the illustrated example, it is rectangular as viewed in the thickness direction z.

The second-terminal tip portion 1222 is located downward in the thickness direction z with respect to the second-terminal base portion 1221. The second-terminal tip portion 1222 is used to surface-mount the semiconductor device A10 on a circuit board or the like. The second-terminal tip portion 1222 extends in the first direction x. In the illustrated example, the second-terminal tip portion 1222 is inclined to the x-y plane, as shown in FIG. 12. Unlike this example, the second-terminal tip portion 1222 may be parallel to the x-y plane.

The second-terminal intermediate portion 1223 is located between the second-terminal base portion 1221 and the second-terminal tip portion 1222. The second-terminal intermediate portion 1223 extends downward in the thickness direction z from the second-terminal base portion 1221. In the illustrated example, the second-terminal intermediate portion 1223 is inclined to the thickness direction z (the y-z plane). Unlike this example, the second-terminal intermediate portion 1223 may be parallel to the thickness direction z. As such, the dimension of the semiconductor device A10 can be reduced in the first direction x. On the other hand, the configuration in which the second-terminal intermediate portion 1223 is inclined to the thickness direction z facilitates manufacturing of the semiconductor device A10 (e.g., bending of each second terminal portion 122). The shape of the second-terminal intermediate portion 1223 is not particularly limited.

Each of the second terminal portions 122 is covered with the metal layer 120 except for the tip surface of the second-terminal tip portion 1222. In other words, in each second terminal portion 122, the tip surface of the second-terminal tip portion 1222 is exposed from the metal layer 120. The tip surface refers to the end surface of the second-terminal tip portion 1222 opposite to the end connected to the second-terminal intermediate portion 1223.

The third lead 13 is spaced apart from the first lead 11 (the die pad portion 111) to the second side in the first direction x. The third lead 13 is aligned with the second lead 12 in the second direction y. The third lead 13 includes a metal layer 130, a pad portion 131, and a third terminal portion 132.

The pad portion 131 has a third lead obverse surface 1311 and a third lead reverse surface 1312. The third lead obverse surface 1311 faces downward in the thickness direction z. The third lead reverse surface 1312 faces upward in the thickness direction z. The third lead obverse surface 1311 is connected to a connecting member 32. The shape of the pad portion 131 is not particularly limited. In the illustrated example, the pad portion 131 has a rectangular shape as viewed in the thickness direction z. As viewed in the thickness direction z, the pad portion 131 is smaller than the pad portion 121. The thickness (the dimension in the thickness direction z) of the pad portion 131 is smaller than the thickness (the dimension in the thickness direction z) of the die pad portion 111, and is the same as the thickness (the dimension in the thickness direction z) of the pad portion 121. In the illustrated example, the third lead obverse surface 1311 is located at the same position as the first lead obverse surface 1111 of the die pad portion 111 in the thickness direction z.

The third terminal portion 132 is connected to the pad portion 131. A large part of the third terminal portion 132 is exposed from the sealing resin 40. The third terminal portion 132 protrudes to the second side in the first direction x with respect to the sealing resin 40. Thus, the third terminal portion 132 is disposed on the side opposite to the first terminal portion 112 in the first direction x with the sealing resin 40 interposed therebetween. The third terminal portion 132 is disposed on a second side in the second direction y with respect to the second terminal portions 122. The third terminal portion 132 is bent into a gull-wing shape. As shown in FIG. 14, the third terminal portion 132 includes a base portion 1321, a tip portion 1322, and an intermediate portion 1323.

The base portion 1321 is connected to the pad portion 131, and extends from the pad portion 131 to the second side in the first direction x. In the illustrated example, the base portion 1321 is parallel to the x-y plane. The shape of the base portion 1321 is not particularly limited, and in the illustrated example, it is rectangular as viewed in the thickness direction z. The base portion 1321 includes a section covered with the sealing resin 40, and a section exposed from the sealing resin 40.

The tip portion 1322 is located downward in the thickness direction z with respect to the base portion 1321. The tip portion 1322 is used to surface-mount the semiconductor device A10 on a circuit board or the like. The tip portion 1322 extends in the first direction x as viewed in the thickness direction z. In the illustrated example, the tip portion 1322 is inclined to the x-y plane, as shown in FIG. 14. Unlike this example, the tip portion 1322 may be parallel to the x-y plane.

The intermediate portion 1323 is interposed between the base portion 1321 and the tip portion 1322. The intermediate portion 1323 extends downward in the thickness direction z from the base portion 1321. In the illustrated example, the intermediate portion 1323 is inclined to the thickness direction z (the y-z plane). Unlike this example, the intermediate portion 1323 may be parallel to the thickness direction z. As such, the dimension of the semiconductor device A10 can be reduced in the first direction x. On the other hand, the configuration in which the intermediate portion 1323 is inclined to the thickness direction z facilitates manufacturing of the semiconductor device A10 (e.g., bending of the third terminal portion 132). The shape of the intermediate portion 1323 is not particularly limited.

The third terminal portion 132 is covered with the metal layer 130 except for the tip surface of the tip portion 1322. In other words, the tip surface of the tip portion 1322 is exposed from the metal layer 130. The tip surface refers to the end surface of the tip portion 1322 opposite to the end connected to the intermediate portion 1323.

The fourth lead 14 is spaced apart from the first lead 11 (the die pad portion 111) to the second side in the first direction x. The fourth lead 14 is located between the second lead 12 and the third lead 13 in the second direction y. The fourth lead 14 includes a metal layer 140, a pad portion 141, and a fourth terminal portion 142.

The pad portion 141 has a fourth lead obverse surface 1411 and a fourth lead reverse surface 1412. The fourth lead obverse surface 1411 faces downward in the thickness direction z. The fourth lead reverse surface 1412 faces upward in the thickness direction z. The fourth lead obverse surface 1411 is connected to a connecting member 33. The shape of the pad portion 141 is not particularly limited. In the illustrated example, the pad portion 141 has a rectangular shape as viewed in the thickness direction z. As viewed in the thickness direction z, the pad portion 141 is smaller than the pad portion 121, and has substantially the same size as the pad portion 131. The thickness (the dimension in the thickness direction z) of the pad portion 141 is smaller than the thickness (the dimension in the thickness direction z) of the die pad portion 111, and is the same as the thickness (the dimension in the thickness direction z) of each of the pad portion 121 and the pad portion 131. In the illustrated example, the fourth lead obverse surface 1411 is located at the same position as the first lead obverse surface 1111 of the die pad portion 111 in the thickness direction z.

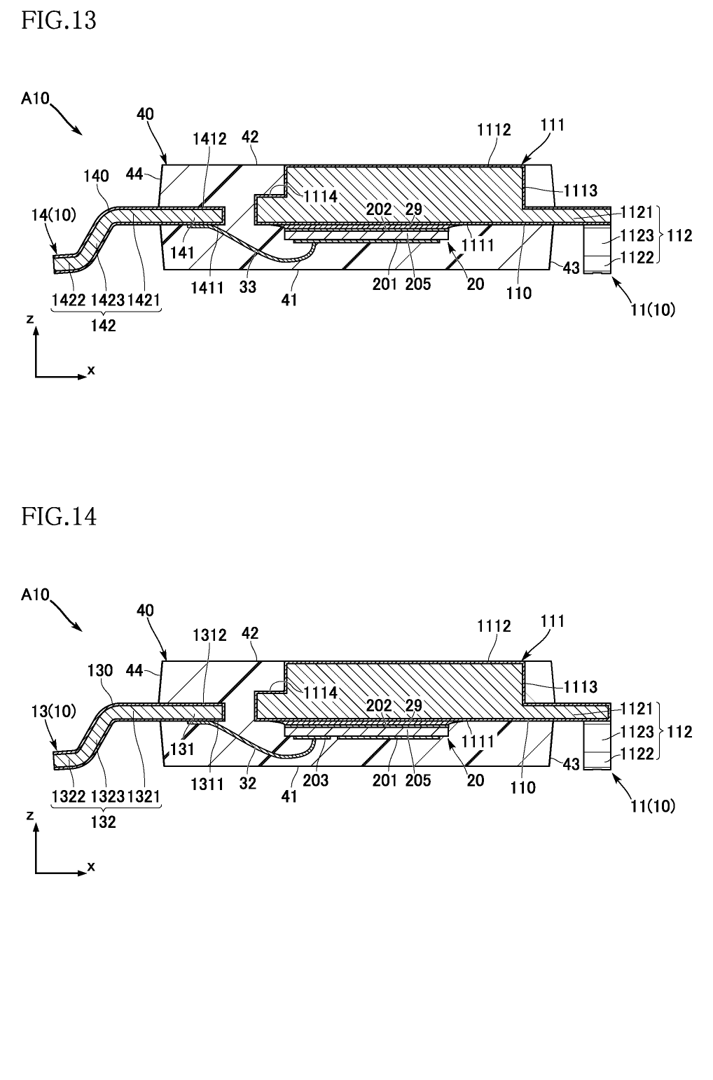

The fourth terminal portion 142 is connected to the pad portion 141. A large part of the fourth terminal portion 142 is exposed from the sealing resin 40. The fourth terminal portion 142 protrudes to the second side in the first direction x with respect to the sealing resin 40. Thus, the fourth terminal portion 142 is disposed on the side opposite to the first terminal portion 112 in the first direction x with the sealing resin 40 interposed therebetween. The fourth terminal portion 142 is disposed on the second side in the second direction y with respect to the second terminal portions 122, and is located between the group of second terminal portions 122 and the third terminal portion 132 in the second direction y. The fourth terminal portion 142 is bent into a gull-wing shape. As shown in FIG. 13, the fourth terminal portion 142 includes a base portion 1421, a tip portion 1422, and an intermediate portion 1423.

The base portion 1421 is connected to the pad portion 141, and extends from the pad portion 141 to the second side in the first direction x. In the illustrated example, the base portion 1421 is parallel to the x-y plane. The shape of the base portion 1421 is not particularly limited, and in the illustrated example, it is rectangular as viewed in the thickness direction z. The base portion 1421 includes a section covered with the sealing resin 40, and a section exposed from the sealing resin 40.

The tip portion 1422 is located downward in the thickness direction z with respect to the base portion 1421. The tip portion 1422 is used to surface-mount the semiconductor device A10 on a circuit board or the like. The tip portion 1422 extends in the first direction x as viewed in the thickness direction z. In the illustrated example, the tip portion 1422 is inclined to the x-y plane, as shown in FIG. 13. Unlike this example, the tip portion 1422 may be parallel to the x-y plane.

The intermediate portion 1423 is interposed between the base portion 1421 and the tip portion 1422. The intermediate portion 1423 extends downward in the thickness direction z from the base portion 1421. In the illustrated example, the intermediate portion 1423 is inclined to the thickness direction z (the y-z plane). Unlike this example, the intermediate portion 1423 may be parallel to the thickness direction z. As such, the dimension of the semiconductor device A10 can be reduced in the first direction x. On the other hand, the configuration in which the intermediate portion 1423 is inclined to the thickness direction z facilitates manufacturing of the semiconductor device A10 (e.g., bending of the fourth terminal portion 142). The shape of the intermediate portion 1423 is not particularly limited.

The fourth terminal portion 142 is covered with the metal layer 140 except for the tip surface of the tip portion 1422. In other words, the tip surface of the tip portion 1422 is exposed from the metal layer 140. The tip surface refers to the end surface of the tip portion 1422 opposite to the end connected to the intermediate portion 1423.

In the semiconductor device A10, as shown in FIG. 6, the width W1123 of each first-terminal intermediate portion 1123 of the first lead 11 is at least 0.5 times and at most twice the width W1223 of each second-terminal intermediate portion 1223 of the second lead 12, for example. The width W1123 of each first-terminal intermediate portion 1123 is a dimension along the following direction, and is an example of the "first dimension" defined in the claims. Said direction is perpendicular to both the thickness direction z and the direction in which the first-terminal intermediate portions 1123 extend as viewed in the thickness direction z. In the present embodiment, the direction is the first direction x. In other words, in the present embodiment, the width W1123 of each first-terminal intermediate portion 1123 is the dimension of the first-terminal intermediate portion 1123 in the first direction x. The width W1223 of each second-terminal intermediate portion 1223 is a dimension along the following direction, and is an example of the "second dimension" defined in the claims. Said direction is perpendicular to both the thickness direction z and the direction in which each second-terminal intermediate portion 1223 extends as viewed in the thickness direction z. In the present embodiment, the direction is the second direction y. In other words, in the present embodiment, the width W1223 of each second-terminal intermediate portion 1223 is the dimension of each second-terminal intermediate portion 1223 in the second direction y. The relationship between the width W1123 of each first-terminal intermediate portion 1123 and the width W1223 of each second-terminal intermediate portion 1223 is not limited to the example given above.

In the semiconductor device A10, as shown in FIG. 6, the width W1223 of each second-terminal intermediate portion 1223 of the second lead 12, the width W1323 of the intermediate portion 1323 of the third lead 13, and the width W1423 of the intermediate portion 1423 of the fourth lead 14 are the same. The width W1323 of the intermediate portion 1323 is a dimension along the following direction. Said direction is perpendicular to both the thickness direction z and the direction in which the intermediate portion 1323 extends as viewed in the thickness direction z. In the present embodiment, the direction is the second direction y. In other words, in the present embodiment, the width W1323 of the intermediate portion 1323 is the dimension of the intermediate portion 1323 in the second direction y. The width W1423 of the intermediate portion 1423 is a dimension along the following direction. Said direction is perpendicular to both the thickness direction z and the direction in which the intermediate portion 1423 extends as viewed in the thickness direction z. In the present embodiment, the direction is the second direction y. In other words, in the present embodiment, the width W1423 of the intermediate portion 1423 is the dimension of the intermediate portion 1423 in the second direction y. The relationship between the width W1223 of each second-terminal intermediate portion 1223, the width W1323 of the intermediate portion 1323, and the width W1423 of the intermediate portion 1423 is not limited to the example given above.

As shown in FIGS. 4, 9, and FIG. 12 to FIG. 15, the semiconductor element 20 is mounted on the first lead obverse surface 1111 of the die pad portion 111. In the semiconductor device A10, the semiconductor element 20 is an n-channel metal-oxide-semiconductor field-effect transistor (MOSFET) having a vertical structure. The semiconductor element 20 is not limited to a MOSFET. The semiconductor element 20 may be another transistor such as an insulated gate bipolar transistor (IGBT). Further, the semiconductor element 20 may be a diode. The semiconductor element 20 has a semiconductor layer 205, a first electrode 201, a second electrode 202, and a third electrode 203.

The semiconductor layer 205 includes a compound semiconductor substrate. The main material of the compound semiconductor substrate is silicon carbide (SiC). Alternatively, the main material of the compound semiconductor substrate may be silicon (Si).

The first electrode 201 is provided on a surface of the semiconductor layer 205 that faces the same side (downward) in the thickness direction z as the first lead obverse surface 1111 of the die pad portion 111 of the first lead 11. The first electrode 201 corresponds to a source electrode of the semiconductor element 20.

The second electrode 202 is provided on a surface of the semiconductor layer 205 opposite to the first electrode 201 in the thickness direction z. The second electrode 202 faces the first lead obverse surface 1111 of the die pad portion 111 of the first lead 11. The second electrode 202 corresponds to a drain electrode of the semiconductor element 20. In the present embodiment, the second electrode 202 is bonded to the first lead obverse surface 1111 via a bonding layer 29. The bonding layer 29 is solder, silver (Ag) paste, or calcined silver, for example.

The third electrode 203 is provided on the surface of the semiconductor layer 205 in the thickness direction z where the first electrode 201 is provided, and is spaced apart from the first electrode 201. The third electrode 203 corresponds to a gate electrode of the semiconductor element 20. As viewed in the thickness direction z, the area of the third electrode 203 is smaller than that of the first electrode 201.

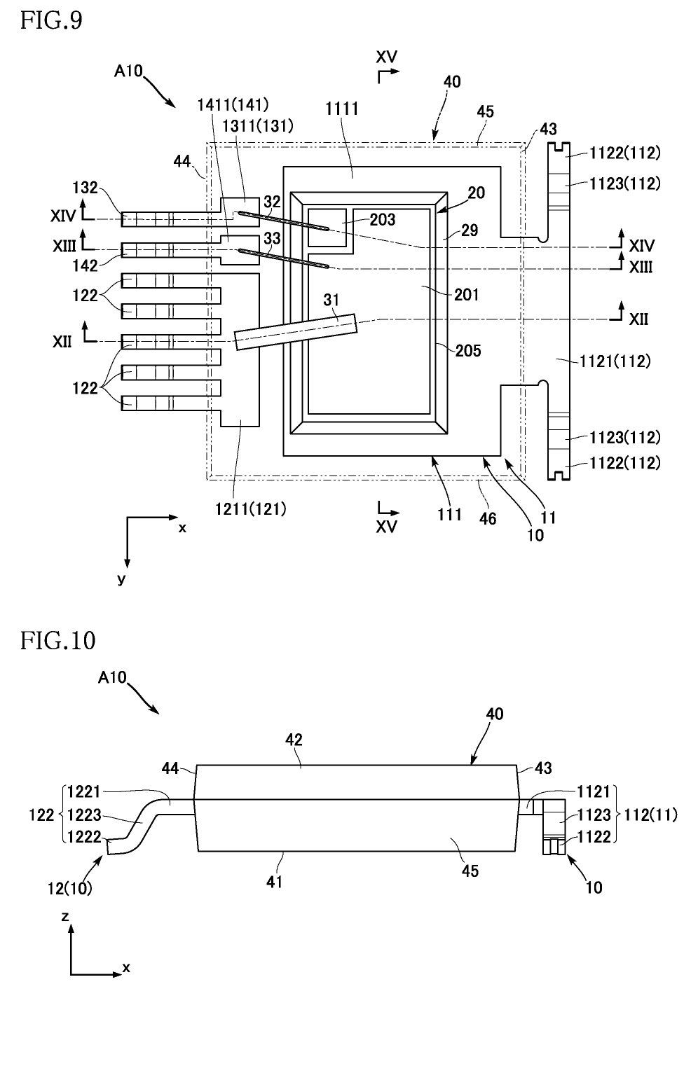

As shown in FIGS. 9 and 12, the connecting member 31 is bonded to the first electrode 201 of the semiconductor element 20 and the second lead obverse surface 1211 of the pad portion 121 of the second lead 12. The material of the connecting member 31 is not particularly limited, and contains a metal such as aluminum (Al), copper (Cu), or gold (Au). The number of connecting members 31 is not particularly limited, and it is possible to provide a plurality of connecting members 31. In the illustrated example, the connecting member 31 is a flat band-like member containing aluminum (Al).

As shown in FIGS. 9 and 14, the connecting member 32 is connected to the third electrode 203 of the semiconductor element 20 and the third lead obverse surface 1311 of the pad portion 131 of the third lead 13. In the illustrated example, the connecting member 32 is a linear member narrower than the connecting member 31, and contains gold (Au).

As shown in FIGS. 9 and 13, the connecting member 33 is connected to the first electrode 201 of the semiconductor element 20 and the fourth lead obverse surface 1411 of the pad portion 141 of the fourth lead 14. In the illustrated example, the connecting member 33 is a linear member narrower than the connecting member 31, and contains gold (Au).

In the present embodiment, the first terminal portion 112 of the first lead 11 is a drain terminal, the second terminal portions 122 of the second lead 12 are source terminals, the third terminal portion 132 of the third lead 13 is a gate terminal, and the fourth terminal portion 142 of the fourth lead 14 is a source sense terminal.

As shown in FIGS. 1 to 18, the sealing resin 40 covers the semiconductor element 20, the connecting members 31, 32, and 33, and respective parts of the first lead 11, the second lead 12, the third lead 13, and the fourth lead 14. The sealing resin 40 is electrically insulative. The sealing resin 40 is made of a material containing a black epoxy resin, for example. The sealing resin 40 has a first resin surface 41, a second resin surface 42, a third resin surface 43, a fourth resin surface 44, a fifth resin surface 45, and a sixth resin surface 46.

The first resin surface 41 faces the same side (downward) in the thickness direction z as the first lead obverse surface 1111 of the die pad portion 111 of the first lead 11. The second resin surface 42 faces the opposite side (upward) to the first resin surface 41 in the thickness direction z. The first lead reverse surface 1112 of the die pad portion 111 of the first lead 11 is exposed from the second resin surface 42. The second resin surface 42 and the first lead reverse surface 1112 are flush with each other. The first lead reverse surface 1112 is spaced apart from the third resin surface 43 in the first direction x.

The third resin surface 43 faces the first side in the first direction x. The first-terminal base portion 1121 of the first terminal portion 112 of the first lead 11 passes through the third resin surface 43. In the present embodiment, only one first-terminal base portion 1121 passes through the third resin surface 43. The first-terminal base portion 1121 is spaced apart from the second resin surface 42 in the thickness direction z.

The fourth resin surface 44 faces the opposite side (the second side) to the third resin surface 43 in the first direction x. In the present embodiment, the second-terminal base portions 1221 of the second terminal portions 122 of the second lead 12, the base portion 1321 of the third terminal portion 132 of the third lead 13, and the base portion 1421 of the fourth terminal portion 142 of the fourth lead 14 pass through the fourth resin surface 44.

The fifth resin surface 45 and the sixth resin surface 46 face away from each other in the second direction y. The sixth resin surface 46 faces a first side in the second direction y, and the fifth resin surface 45 faces the second side in the second direction y.

As shown in FIG. 8, the ends of the two first-terminal tip portions 1122 of the first terminal portion 112 of the first lead 11 in the second direction y are located at substantially the same positions as the fifth resin surface 45 and the sixth resin surface 46 of the sealing resin 40 in the second direction y. The ends of the two first-terminal tip portions 1122 in the second direction y may or may not extend outward beyond the fifth resin surface 45 and the sixth resin surface 46 in the second direction y.

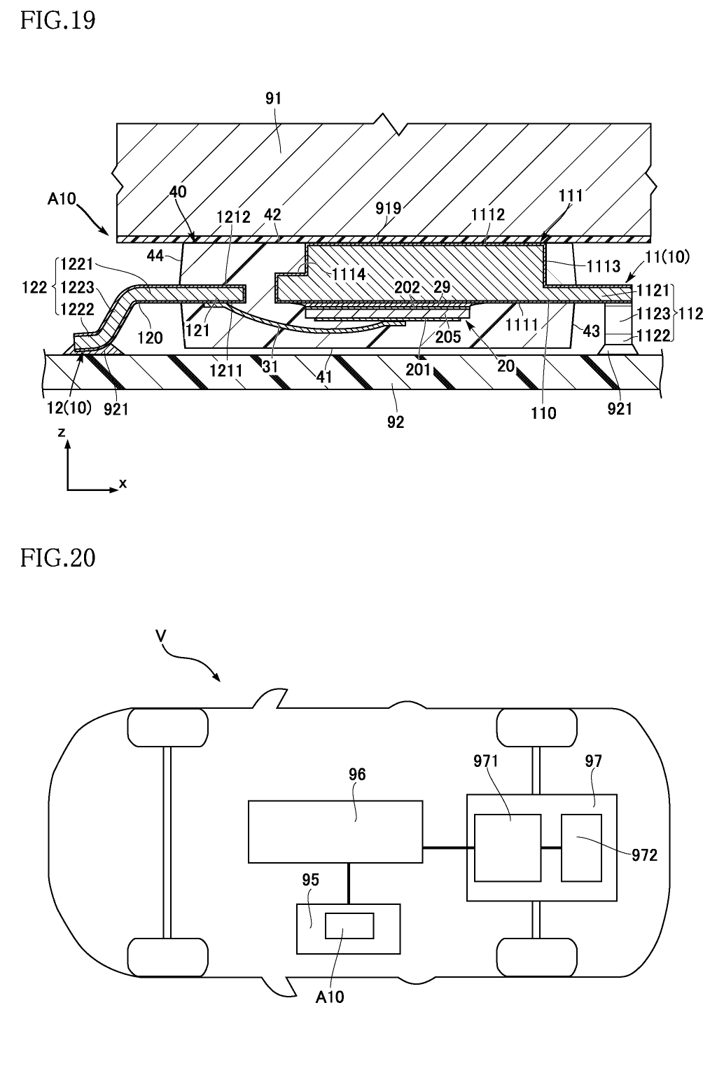

FIG. 19 shows the semiconductor device A10 in use. In this use example, the semiconductor device A10 is surface-mounted on a circuit board 92. In other words, the first-terminal tip portions 1122 of the first terminal portion 112, the second-terminal tip portions 1222 of the second terminal portions 122, the tip portion 1322 of the third terminal portion 132, and the tip portion 1422 of the fourth terminal portion 142 are electrically connected to a wiring pattern (not illustrated) of the circuit board 92 by, for example, solder 921. A heat sink 91 is disposed to face the first lead reverse surface 1112 of the die pad portion 111. In the illustrated example, a sheet member 919 is provided between the first lead reverse surface 1112 and the heat sink 91. The sheet member 919 is an insulating sheet, for example. In the illustrated example, there is a small gap between the sealing resin 40 (the first resin surface 41) and the circuit board 92. However, the first resin surface 41 may be in contact with the circuit board 92.

FIG. 20 shows a vehicle V provided with the semiconductor device A10. The vehicle V is an electric vehicle (EV), for example.

As shown in FIG. 20, the vehicle V includes an on-board charger 95, a storage battery 96, and a drive system 97. The on-board charger 95 receives power wirelessly from an outdoor power supply facility (not illustrated). Alternatively, the on-board charger 95 may receive power from the power supply facility via a wired connection. The on-board charger 95 includes a step-up DC-DC converter. As shown in FIG. 20, the semiconductor device A10 is a part of the on-board charger 95, and may be used for the DC-DC converter. The voltage of the power supplied to the on-board charger 95 is boosted by the converter and then supplied to the storage battery 96. The voltage is boosted to 600 V, for example.

The drive system 97 drives the vehicle V. The drive system 97 includes an inverter 971 and a drive source 972. The power stored in the storage battery 96 is supplied to the inverter 971. The power supplied from the storage battery 96 to the inverter 971 is DC power. Unlike the power system shown in FIG. 20, a step-up DC-DC converter may be additionally provided between the storage battery 96 and the inverter 971. The inverter 971 converts the DC power into AC power. The inverter 971 is electrically connected to the drive source 972. The drive source 972 includes an AC motor and a transmission. The AC power converted by the inverter 971 is supplied to the drive source 972 to rotate the AC motor, and the rotation of the AC motor is transmitted to the transmission. The transmission appropriately reduces the rotational speed transmitted from the AC motor and rotates the drive shaft of the vehicle V. This drives the vehicle V. Driving the vehicle V requires freely regulating the rotational speed of the AC motor based on the amount of accelerator pedal operation and other information. Thus, the inverter 971 is necessary in order to output the AC power at a frequency appropriately adjusted to correspond to the required rotational speed of the AC motor.

FIG. 21 shows a step of a method for manufacturing the semiconductor device A10. In the step shown in FIG. 21, the conductive member 10 is in the form of a lead frame 80 before being separated into the first lead 11, the second lead 12, the third lead 13, and the fourth lead 14.

As shown in FIG. 21, the lead frame 80 includes a frame body 81. The frame body 81 connects the first lead 11, the second lead 12, the third lead 13, and the fourth lead 14 to each other. Each connecting portion between the first lead 11 and the frame body 81 is formed with a through-hole 1120. The shape of the through-hole 1120 as viewed in the thickness direction z is not particularly limited, but in the illustrated example, it is rectangular. In this state, the lead frame 80 is plated. As a result, the surface of the lead frame 80 is covered with a thin metal film formed by plating, and the inside of the through-hole 1120 is also covered with the thin metal film. The thin metal film will become each of the metal layers 110, 120, 130, and 140.

After the plating, the semiconductor element 20 is mounted, the connecting members 31, 32, and 33 are bonded, and the sealing resin 40 is formed. Then, the lead frame 80 is cut along cut lines CL to separate the first lead 11, the second lead 12, the third lead 13, and the fourth lead 14 from the frame body 81, and the first terminal portion 112 of the first lead 11, the second terminal portions 122 of the second lead 12, the third terminal portion 132 of the third lead 13, and the fourth terminal portion 142 of the fourth lead 14 are bent. The order of cutting along the cut lines CL and bending the first terminal portion 112 of the first lead 11, the second terminal portions 122 of the second lead 12, the third terminal portion 132 of the third lead 13, and the fourth terminal portion 142 of the fourth lead 14 may be reversed, or they may be performed simultaneously. The semiconductor device A10 is formed through the above process.

The semiconductor device A10 has the following advantages.

As shown in FIG. 19, the first lead reverse surface 1112 is exposed from the second resin surface 42. This makes it possible to arrange the heat sink 91 to face the first lead reverse surface 1112, for example. The first-terminal tip portions 1122 are located downward in the thickness direction z from the first-terminal base portion 1121. This makes it possible to surface-mount the semiconductor device A10 on the circuit board 92, for example, by using the first-terminal tip portions 1122. The first lead reverse surface 1112 is spaced apart from the third resin surface 43 in the first direction x. The first-terminal base portion 1121 is spaced apart from the second resin surface 42 in the thickness direction z. Thus, a part of the sealing resin 40 exists between the first lead reverse surface 1112 and the first-terminal base portion 1121. In this way, the first lead 11 can be more firmly held by the sealing resin 40.

The first terminal portion 112 has the first-terminal tip portions 1122, and each of the first-terminal tip portions 1122 has a first tip surface 1122a and a recessed surface 1122d. The first tip surface 1122a is exposed from the metal layer 110, and the recessed surface 1122d is covered with the metal layer 110. In this configuration, the area of each first-terminal tip portion 1122 that is covered with the metal layer 110 is increased. This makes it possible to increase the mounting strength of the semiconductor device A10.

The first tip surface 1122a includes two exposed areas 1122b, which are spaced apart from each other in the first direction x. With this configuration, the recessed surface 1122d is connected to the upper surface (the surface facing in the thickness direction z) of the first-terminal tip portion 1122 and the lower surface (the surface facing in the thickness direction z) of the first-terminal tip portion 1122, which makes it possible to secure the area of the recessed surface 1122d appropriately. Since the area covered with the metal layer 110 is appropriately secured in the first terminal portion 112, insufficient mounting strength of the semiconductor device A10 can be prevented.

The first terminal portion 112 has the first-terminal intermediate portions 1123. This makes it possible to support the first-terminal tip portions 1122 more reliably.

The first terminal portion 112 has the two first-terminal tip portions 1122. This makes it possible to increase the mounting strength of the semiconductor device A10.

The two first-terminal tip portions 1122 extend outward from the two respective first-terminal intermediate portions 1123 in the second direction y. This makes it possible to further increase the mounting strength of the semiconductor device A10.

The size of the first-terminal base portion 1121 in the second direction y is smaller than the size of the die pad portion 111 in the second direction y. This further improves the force with which the sealing resin 40 holds the first lead 11.

The first-terminal tip portions 1122 do not extend beyond the first-terminal intermediate portions 1123 in the first direction x. This reduces the dimension of the semiconductor device A10 in the first direction x.

The size of the die pad portion 111 in the thickness direction z is larger than the size of the first-terminal base portion 1121 in the thickness direction z. This makes it possible to transfer heat over a wider area in the first direction x and the second direction y during the process of heat transfer from the semiconductor element 20 to the first lead reverse surface 1112. Thus, the heat from the semiconductor element 20 can be dissipated to the heat sink 91, etc., via a wider area than the first-terminal base portion 1121, thereby improving heat dissipation efficiency.

The lower surface (the surface facing downward in the thickness direction z) of the first-terminal base portion 1121 is flush with the first lead obverse surface 1111. This makes it possible to increase the distance from the first-terminal base portion 1121 to the third resin surface 43 in the thickness direction z, thereby further improving the force with which the sealing resin 40 holds the first lead 11.

The first terminal portion 112 is formed with the depressions 113. With this configuration, even if the sealing resin 40 spreads along the base side surfaces 1121a during the formation of the sealing resin 40, the sealing resin 40 is prevented from being formed beyond the depressions 113. Thus, the semiconductor device A10 can suppress resin burrs. In particular, the depressions 113 of the semiconductor device A10 are formed in the base side surfaces 1121a of the first-terminal base portion 1121 of the first terminal portion 112, as viewed in the thickness direction z. This can suppress resin burrs formed on the first-terminal tip portions 1122. Accordingly, when the semiconductor device A10 is surface-mounted on the circuit board 92 or the like, it is possible to suppress resin burrs interposed between each first-terminal tip portion 1122 and the circuit board 92 or the like. As a result, mounting defects of the semiconductor device A10 can be reduced. Since resin burrs on the first-terminal intermediate portions 1123 are suppressed, it is possible to suppress potential processing defects caused by the resin burrs when the first-terminal intermediate portions 1123 are bent.

The following describes other embodiments and variations of the semiconductor device of the present disclosure. The configurations of the elements in each of the embodiments and variations can be combined as appropriate as long as the combination does not cause technical contradictions.

### SECOND EMBODIMENT:

FIGS. 22 to 25 show a semiconductor device A20 according to a second embodiment. The semiconductor device A20 is different from the semiconductor device A10 in that the first tip surface 1122a of each first-terminal tip portion 1122 has a connecting area 1122c. Unless otherwise specified, the following description of the connecting area 1122c applies to the first tip surface 1122a of each first-terminal tip portion 1122.

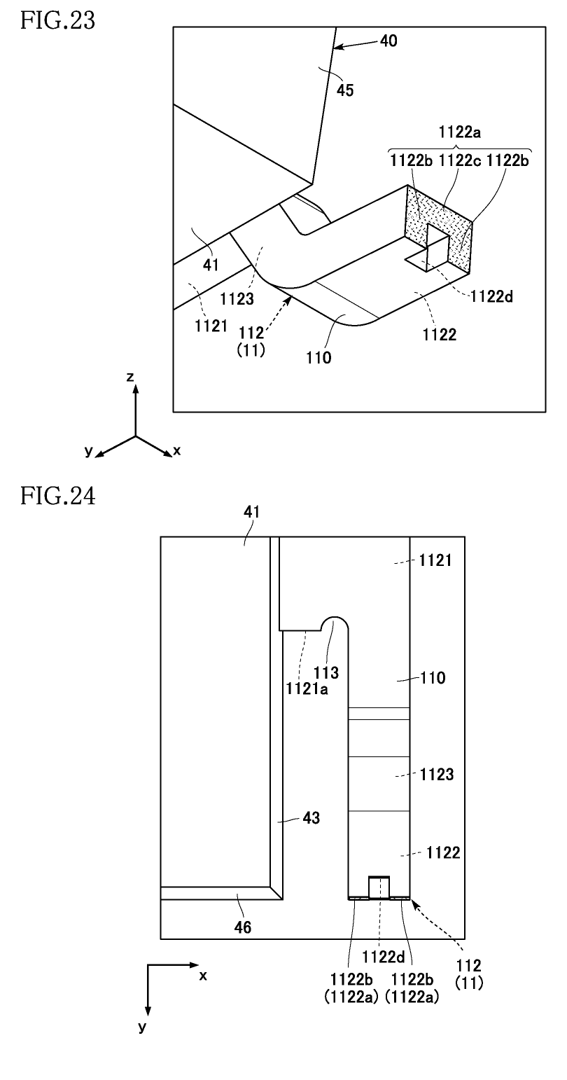

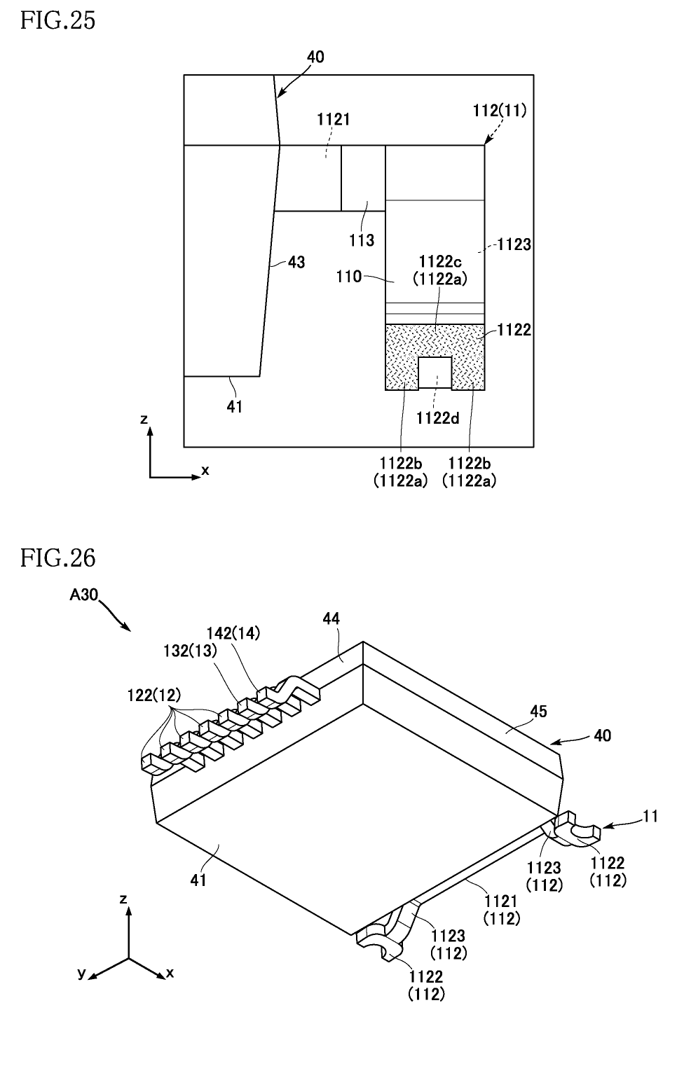

As shown in FIGS. 23 and 25, the connecting area 1122c is connected to two exposed areas 1122b. In the illustrated example, the connecting area 1122c is located upward in the thickness direction z. Thus, the connecting area 1122c is connected to the upper surface (the surface facing upward in the thickness direction z) of the first-terminal tip portion 1122, and the recessed surface 1122d is connected to the lower surface (the surface facing downward in the thickness direction z) of the first-terminal tip portion 1122. Unlike the illustrated example, the connecting area 1122c may be located downward in the thickness direction z. In this case, the connecting area 1122c may be connected to the lower surface (the surface facing downward in the thickness direction z) of the first-terminal tip portion 1122, and the recessed surface 1122d may be connected to the upper surface (the surface facing upward in the thickness direction z) of the first-terminal tip portion 1122.

The shape of each first-terminal tip portion 1122 as described above may be formed as follows. That is, in the state of the lead frame 80 shown in FIG. 21, a groove that is recessed from the lower side (the bottom surface) in the thickness direction z is formed instead of a through-hole 1120. In this way, a connecting area 1122c is formed at a first tip surface 1122a by a subsequent cutting process along the cut lines CL.

The present embodiment allows surface-mounting of the semiconductor device A20 by using the first-terminal tip portions 1122. As with the semiconductor device A10, the semiconductor device A20 includes the first tip surfaces 1122a exposed from the metal layer 110 and the recessed surfaces 1122d covered with the metal layer 110. Thus, according to the present embodiment, the area of each first-terminal tip portion 1122 that is covered with the metal layer 110 is increased, which makes it possible to increase the mounting strength of the semiconductor device A20. Note that the area of each recessed surface 1122d of the semiconductor device A10 is larger than the area of each recessed surface 1122d of the semiconductor device A20. In other words, the semiconductor device A10 is more preferable for increasing the mounting strength of the semiconductor device according to the present disclosure. Further, as with the semiconductor device A10, the semiconductor device A20 includes the depressions 113 formed in the first terminal portion 112. Thus, the present embodiment can suppress resin burrs and reduce defects (e.g., mounting defects and processing defects as described above) of the semiconductor device A20 caused by the resin burrs. Further, the semiconductor device A20 has advantages similar to the semiconductor device A10 owing to its common configuration with the semiconductor device A10.

### THIRD EMBODIMENT:

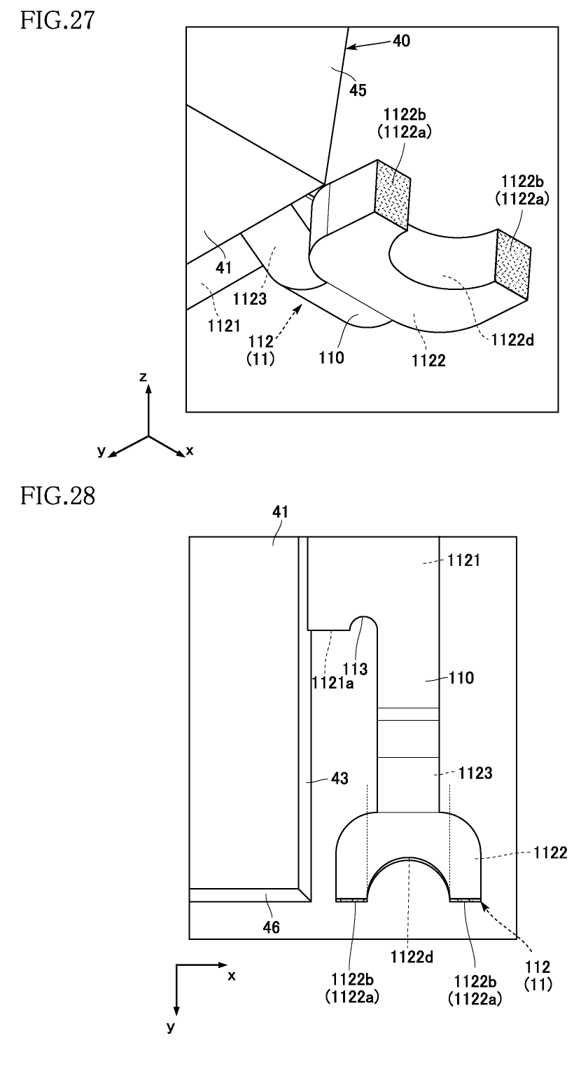

FIGS. 26 to 29 show a semiconductor device A30 according to a third embodiment. The semiconductor device A30 is different from the semiconductor device A10 in the shape of each first-terminal tip portion 1122.

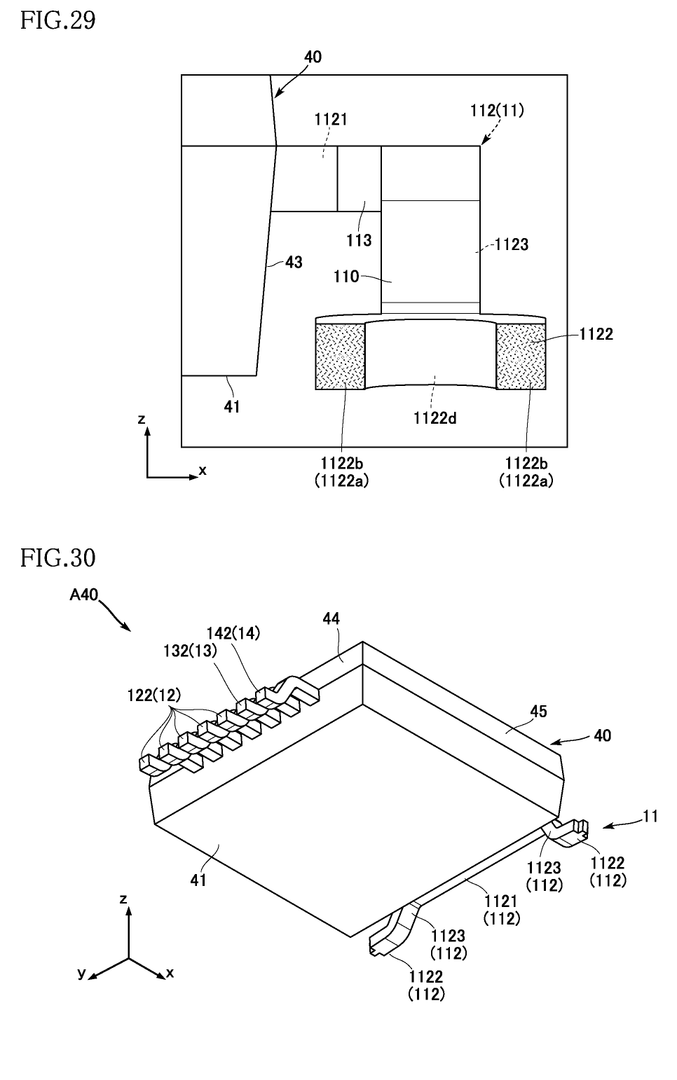

As shown in FIGS. 26 to 29, in the semiconductor device A30, the end of each of the two first-terminal tip portions 1122 in the second direction y is bifurcated. As shown in FIGS. 28 and 29, the bifurcated end of each of the two first-terminal tip portions 1122 extends to both sides in the first direction x relative to the portion connected to the corresponding first-terminal intermediate portion 1123. Thus, two exposed areas 1122b are located outside the corresponding first-terminal intermediate portion 1123 as viewed from the first tip surface 1122a in the direction connected to the first-terminal intermediate portion 1123.

The present embodiment allows surface-mounting of the semiconductor device A30 by using the first-terminal tip portions 1122. As with the semiconductor device A10, the semiconductor device A30 includes the first tip surfaces 1122a exposed from the metal layer 110 and the recessed surfaces 1122d covered with the metal layer 110. Thus, according to the present embodiment, the area of each first-terminal tip portion 1122 that is covered with the metal layer 110 is increased, which makes it possible to increase the mounting strength of the semiconductor device A30. In particular, since the area of each recessed surface 1122d of the semiconductor device A30 is larger than the area of each recessed surface 1122d of the semiconductor device A10, the semiconductor device A30 is more preferable for increasing the mounting strength of the semiconductor device according to the present disclosure. Further, as with the semiconductor device A10, the semiconductor device A30 includes the depressions 113 formed in the first terminal portion 112. Thus, the present embodiment can also suppress resin burrs and reduce defects (e.g., mounting defects and processing defects as described above) of the semiconductor device A30 caused by the resin burrs. Further, the semiconductor device A30 has advantages similar to the semiconductor devices A10 and A20 owing to its common configuration with the semiconductor devices A10 and A20.

The area of each recessed surface 1122d in the semiconductor device A30 is larger than the area of each recessed surface 1122d in the semiconductor device A10. With this configuration, the area of each first-terminal tip portion 1122 that is covered with the metal layer 110 is further increased, which makes it possible to further increase the mounting strength of the semiconductor device A30.

### FOURTH EMBODIMENT:

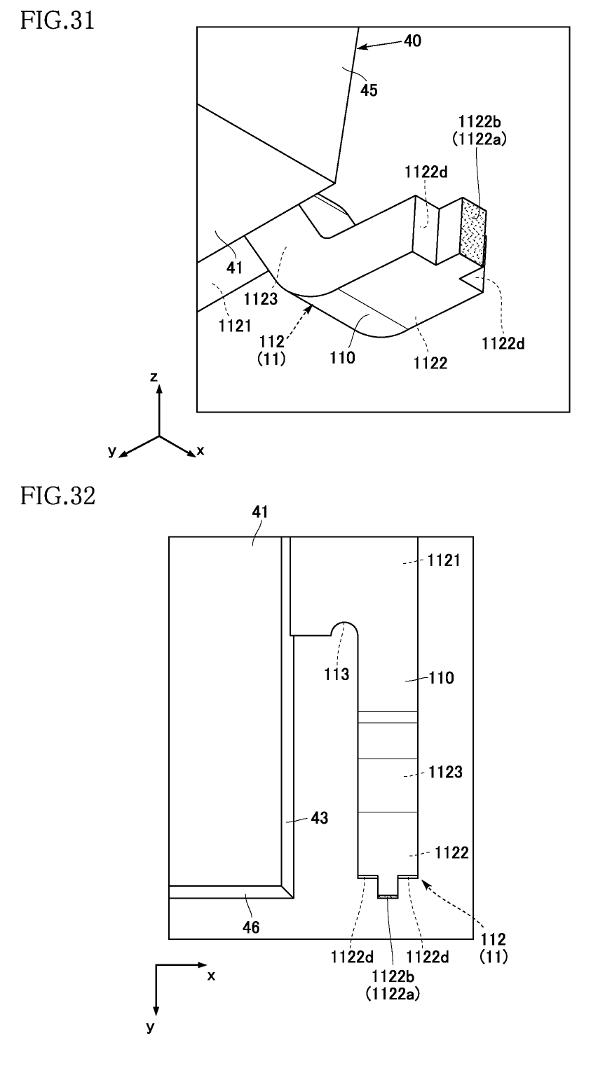

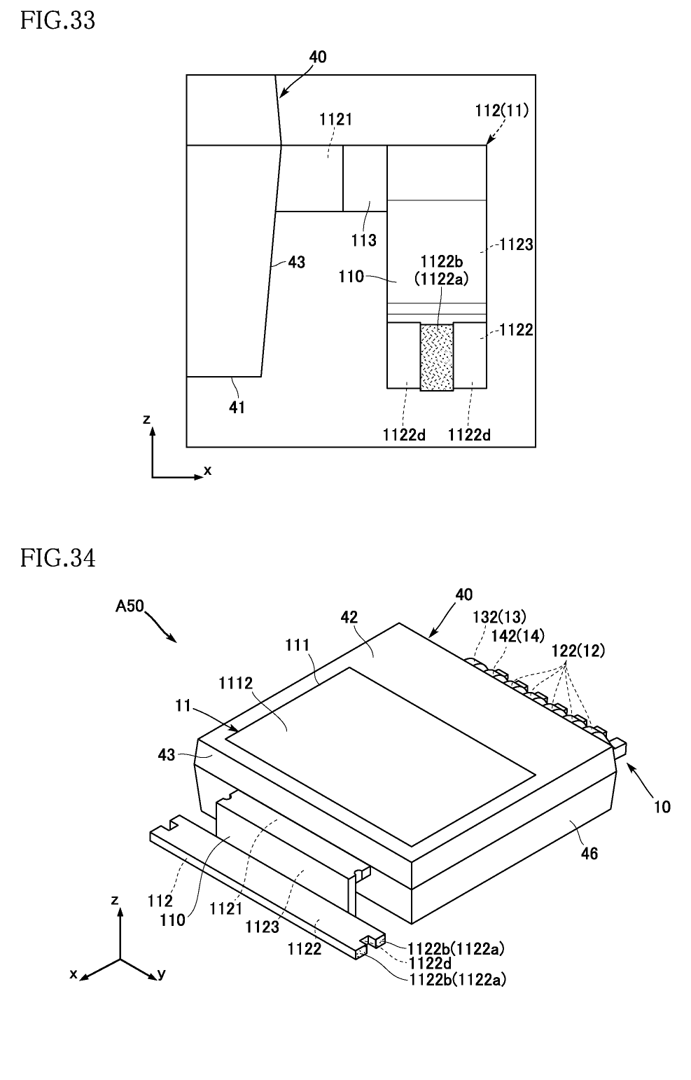

FIGS. 30 to 33 show a semiconductor device A40 according to a fourth embodiment. The semiconductor device A40 is different from the semiconductor device A10 in the arrangement of the first tip surface 1122a of each first-terminal tip portion 1122.

In each of the first-terminal tip portions 1122 in the semiconductor device A40, the first tip surface 1122a is flanked by two recessed surfaces 1122d in the first direction x. In other words, the two recessed surfaces 1122d are located on the respective sides of the first tip surface 1122a in the first direction x.

The present embodiment allows surface-mounting of the semiconductor device A40 by using the first-terminal tip portions 1122. As with the semiconductor device A10, the semiconductor device A40 includes the first tip surfaces 1122a exposed from the metal layer 110 and the recessed surfaces 1122d covered with the metal layer 110. Thus, according to the present embodiment, the area of each first-terminal tip portion 1122 that is covered with the metal layer 110 is increased, which makes it possible to increase the mounting strength of the semiconductor device A40. Further, as with the semiconductor device A10, the semiconductor device A40 includes the depressions 113 formed in the first terminal portion 112. Thus, the present embodiment can also suppress resin burrs and reduce defects (e.g., mounting defects and processing defects as described above) of the semiconductor device A40 caused by the resin burrs. Further, the semiconductor device A40 has advantages similar to the semiconductor devices A10, A20, and A30 owing to its common configuration with the semiconductor devices A10, A20, and A30.

In the semiconductor device A40, each of the first-terminal tip portions 1122 includes two recessed surfaces 1122. With this configuration, the area of each first-terminal tip portion 1122 that is covered with the metal layer 110 is further increased, which makes it possible to further increase the mounting strength of the semiconductor device A40.

### FIFTH EMBODIMENT:

FIG. 34 shows a semiconductor device A50 according to a fifth embodiment. The semiconductor device A50 is different from the semiconductor device A10 in the configuration of the first terminal portion 112.

In the semiconductor device A50, the first terminal portion 112 includes a first-terminal base portion 1121, a single first-terminal tip portion 1122, and a single first-terminal intermediate portion 1123. The first-terminal intermediate portion 1123 extends downward in the thickness direction z from the first-terminal base portion 1121, and has a rectangular shape as viewed in the first direction x. The size of the first-terminal intermediate portion 1123 in the second direction y is the same as the size of the first-terminal base portion 1121 in the second direction y.

The first-terminal tip portion 1122 extends from the first-terminal intermediate portion 1123 to the first side (outward) in the first direction x. The first-terminal tip portion 1122 has a rectangular shape elongated in the second direction y, as viewed in the thickness direction z. Both ends of the first-terminal tip portion 1122 in the second direction y protrude outward from the first-terminal intermediate portion 1123 in the second direction y. The respective ends of the first-terminal tip portion 1122 in the second direction y are located at the same (or substantially the same) positions as the fifth resin surface 45 and the sixth resin surface 46 of the sealing resin 40. The ends may or may not protrude outward beyond the fifth resin surface 45 and the sixth resin surface 46 in the second direction y. In the present embodiment, each end of the first-terminal tip portion 1122 in the second direction y is provided with a first tip surface 1122a and a recessed surface 1122d.

The present embodiment allows surface-mounting of the semiconductor device A50 by using the first-terminal tip portion 1122. As with the semiconductor device A10, the semiconductor device A50 includes the first tip surfaces 1122a exposed from the metal layer 110 and the recessed surfaces 1122d covered with the metal layer 110. Thus, according to the present embodiment, the area of the first-terminal tip portion 1122 that is covered with the metal layer 110 is increased, which makes it possible to increase the mounting strength of the semiconductor device A50. Further, as with the semiconductor device A10, the semiconductor device A50 includes the depressions 113 formed in the first terminal portion 112. Thus, the present embodiment can also suppress resin burrs and reduce defects (e.g., mounting defects and processing defects as described above) of the semiconductor device A50 caused by the resin burrs. Further, the semiconductor device A50 has advantages similar to the semiconductor devices A10, A20, and A30 owing to its common configuration with the semiconductor devices A10, A20, and A30. As can be understood from the present embodiment, the specific configurations of the first-terminal tip portion 1122 and the first-terminal intermediate portion 1123 are not particularly limited.

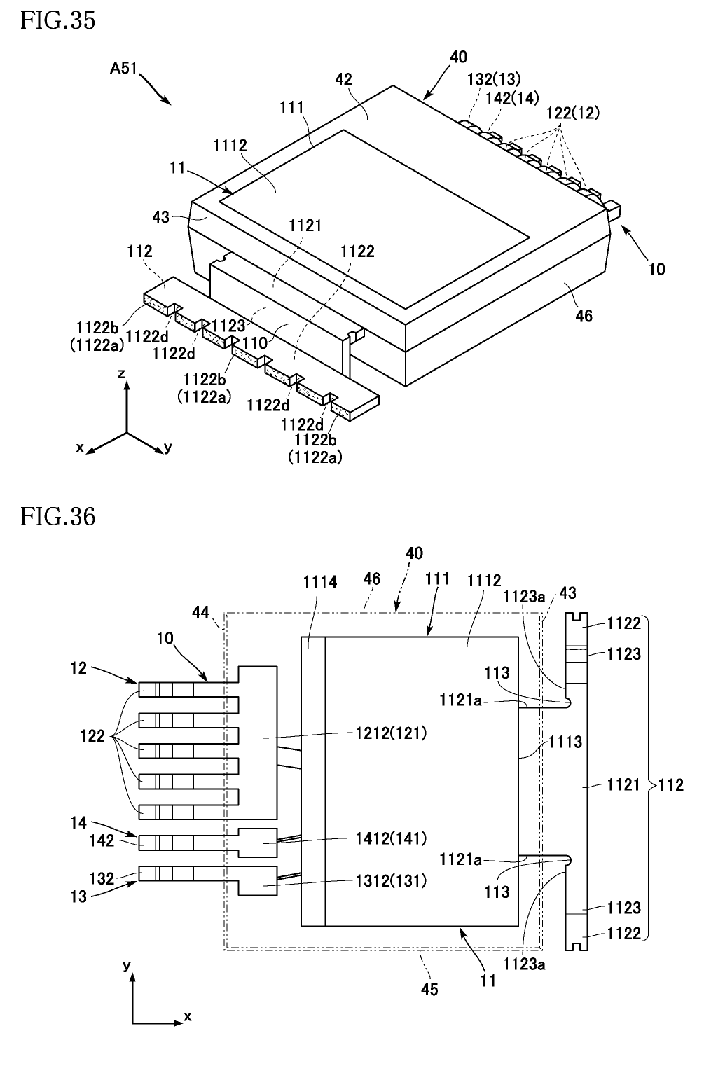

FIG. 35 shows a semiconductor device A51 according to a variation of the fifth embodiment. The semiconductor device A51 is different from the semiconductor device A50 in the arrangement of the first tip surface 1122a and the recessed surface 1122d.

The semiconductor device A51 includes a first tip surface 1122a and a plurality of recessed surfaces 1122d that are arranged at the outer end of the first-terminal tip portion 1122 in the first direction x. The first tip surface 1122a faces the first side in the first direction x. The number of recessed surfaces 1122d in the first-terminal tip portion 1122 in the semiconductor device A51 is not particularly limited, and may be one, for example.

In the case of the semiconductor device A50, both end surfaces of the first-terminal tip portion 1122 in the second direction y are first tip surfaces 1122a. This is because both ends of the first-terminal tip portion 1122 in the second direction y were connected to the frame body 81 of the lead frame 80. On the other hand, in the case of the semiconductor device A51, the end surface of the first-terminal tip portion 1122 on the first side in the first direction x is the first tip surface 1122a. This is because the end of the first-terminal tip portion 1122 on the first side in the first direction x was connected to the frame body 81 of the lead frame 80. As described above, the arrangement of the recessed surfaces 1122d differs depending on the portion(s) at which the first-terminal tip portion 1122 and the frame body 81 of the lead frame 80 were connected.

The present embodiment allows surface-mounting of the semiconductor device A51 by using the first-terminal tip portion 1122. As with the semiconductor device A50, the semiconductor device A51 includes the first tip surface 1122a exposed from the metal layer 110 and the recessed surfaces 1122d covered with the metal layer 110. Thus, according to the present embodiment, the area of the first-terminal tip portion 1122 that is covered with the metal layer 110 is increased, which makes it possible to increase the mounting strength of the semiconductor device A51. Further, as with the semiconductor device A50, the semiconductor device A51 includes the depressions 113 formed in the first terminal portion 112. Thus, the present embodiment can also suppress resin burrs and reduce defects (e.g., mounting defects and processing defects as described above) of the semiconductor device A51 caused by the resin burrs. Further, the semiconductor device A51 has advantages similar to the semiconductor device A50 owing to its common configuration with the semiconductor device A50.

FIGS. 36 to 42 show semiconductor devices according to variations of the present disclosure. FIGS. 36 to 42 show examples where variations are applied to the semiconductor device A10 according to the first embodiment; however, the variations may be applied to the semiconductor devices A20, A30, A40, and A50 according to the other embodiments (the second to fifth embodiments). The semiconductor devices according to the variations described below are each common with the semiconductor device A10 in that the first terminal portion 112 includes first-terminal tip portions 1122. Thus, as with the semiconductor device A10, the semiconductor devices according to the variations described below are surface-mountable by using the first-terminal tip portions 1122. The semiconductor devices according to the variations described below are common with the semiconductor device A10 in that the first tip surfaces 1122a are exposed from the metal layer 110 and the recessed surfaces 1122d are covered with the metal layer 110. Thus, as with the semiconductor device A10, each of the semiconductor devices according to the variations described below is configured such that the area of the first-terminal tip portion 1122 that is covered with the metal layer 110 is increased. This makes it possible to increase the mounting strength of the semiconductor device. Further, the semiconductor devices according to the variations described below are common with the semiconductor device A10 in that the first terminal portion 112 is formed with the depressions 113. Thus, as with the semiconductor device A10, each of the semiconductor devices according to the variations described below can suppress resin burrs and reduce defects (e.g., mounting defects and processing defects as described above) of the semiconductor device caused by the resin burrs.

FIG. 36 shows a semiconductor device according to a first variation. The semiconductor device shown in FIG. 36 is different from the semiconductor device A10 in the arrangement of the depressions 113. In the semiconductor device shown in FIG. 36, each of the two first-terminal intermediate portions 1123 of the first terminal portion 112 has an extending surface 1123a. The pair of extending surfaces 1123a face the third resin surface 43 of the sealing resin 40. The pair of extending surfaces 1123a are connected to the pair of base side surfaces 1121a, respectively. In the present embodiment, each of the two depressions 113 is formed in a respective one of the pair of extending surfaces 1123a. Specifically, in the example shown in FIG. 36, each of the depressions 113 is located at the side of the corresponding extending surface 1123a that is connected to a base side surface 1121a. The arrangement of each depression 113 is not particularly limited as long as the depression 113 is formed in an extending surface 1123a.

As can be understood from the present variation, the semiconductor device of the present disclosure is not limited to the configuration where the depressions 113 are formed in the respective base side surfaces 1121a. Instead, the depressions 113 may be formed in the respective extending surfaces 1123a. Optionally, the depressions 113 may be formed in the upper surface (the surface facing upward in the thickness direction z) of the first-terminal base portion 1121 of the first terminal portion 112 or the lower surface (the surface facing downward in the thickness direction z) of the first-terminal base portion 1121.

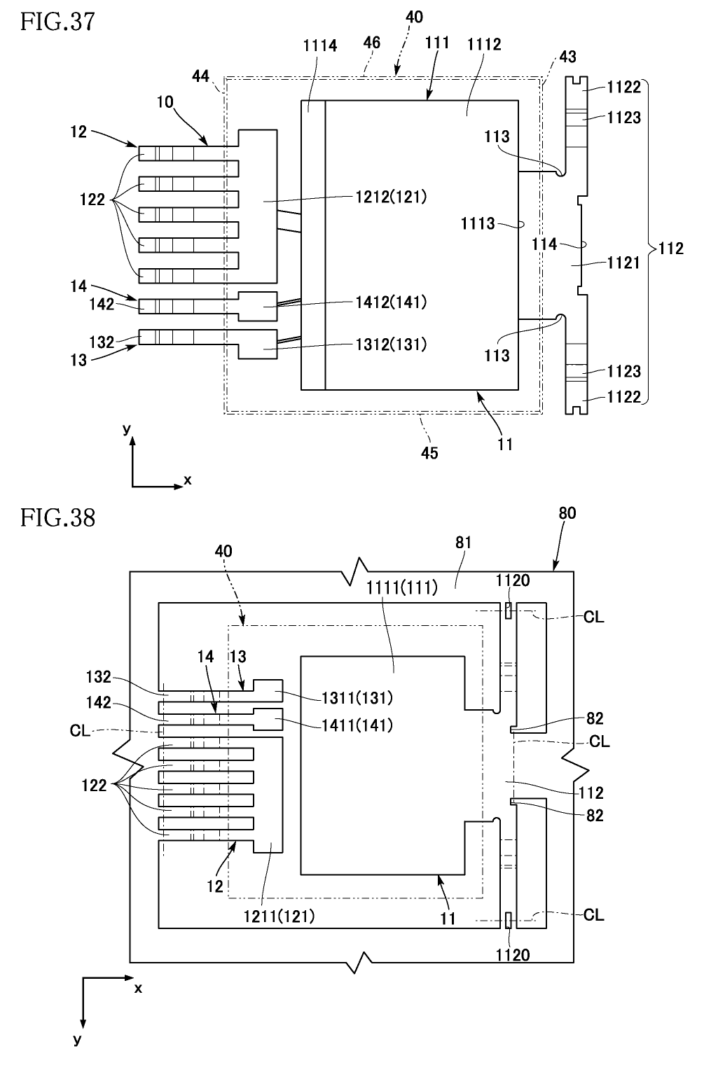

FIG. 37 shows a semiconductor device according to a second variation. The semiconductor device shown in FIG. 37 is different from the semiconductor device A10 in that the first terminal portion 112 includes a recess 114. The recess 114 is formed in the first-terminal base portion 1121. As viewed in the thickness direction z, the recess 114 is recessed from the surface of the first-terminal base portion 1121 that faces the first side in the first direction x.

FIG. 38 shows a step of a method for manufacturing the semiconductor device shown in FIG. 37. As shown in FIG. 38, the first-terminal base portion 1121 is connected to the frame body 81 of the lead frame 80. The lead frame 80 has notches 82 formed in the respective sides of the connected portion in the second direction y. The notches 82 are recessed as viewed in the thickness direction z. During the manufacturing of the semiconductor device shown in FIG. 37, the first-terminal base portion 1121 is cut from the frame body 81 by using the notches 82. As a result, the recess 114 as shown in FIG. 37 is formed. Cutting by using the notches 82 as described above can prevent the surface of the first-terminal base portion 1121 that faces the first side in the first direction x from protruding beyond the surfaces of the first-terminal tip portions 1122 and the first-terminal intermediate portions 1123 that face the first side in the first direction x.

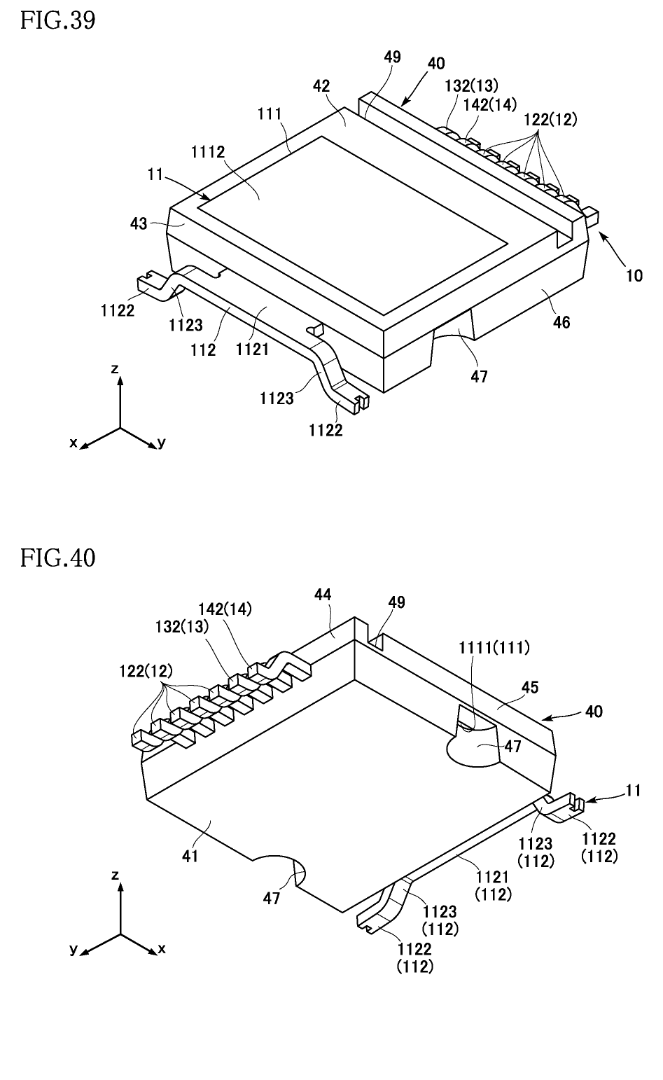

FIGS. 39 and 40 show a semiconductor device according to a third variation. The semiconductor device shown in FIGS. 39 and 40 is different from the semiconductor device A10 in the following respects. First, the sealing resin 40 of the semiconductor device according to the present variation includes a pair of recesses 47. Second, the sealing resin 40 of the semiconductor device according to the present variation includes a groove 49.

One of the recesses 47 is recessed from the first resin surface 41 and the fifth resin surface 45. The other recess 47 is recessed from the first resin surface 41 and the sixth resin surface 46. A part of the first lead obverse surface 1111 is exposed from each of the recesses 47. The pair of recesses 47 are formed because the die pad portion 111 was secured by a jig during the manufacturing of the semiconductor device according to the present variation. In other words, the pair of recesses 47 are marks left by the jig. As described above, since the die pad portion 111 is secured by the jig during the manufacturing of the semiconductor device according to the present variation, the vibration and tilting of the die pad portion 111 can be suppressed. This makes it possible to suppress the bonding defects between the die pad portion 111 and the semiconductor element 20.

The groove 49 is recessed from the second resin surface 42 in the thickness direction z, and extends in the second direction y. The groove 49 extends from the fifth resin surface 45 to the sixth resin surface 46. The groove 49 is located between the first lead reverse surface 1112 and the fourth resin surface 44. The groove 49 of the sealing resin 40 can increase the distance (creepage distance) along the surface of the sealing resin 40 between the first lead reverse surface 1112 (the first lead 11) and each of the second terminal portions 122 (the second lead 12), the third terminal portion 132 (the third lead 13), and the fourth terminal portion 142 (the fourth lead 14). This makes it possible to improve the dielectric strength between the first lead 11 and each of the second lead 12, the third lead 13, and the fourth lead 14. Although a single groove 49 is formed in the sealing resin 40 in the illustrated example, a plurality of grooves 49 may be formed in the sealing resin 40. For example, the plurality of grooves 49 may be arranged in parallel to each other in the first direction x.

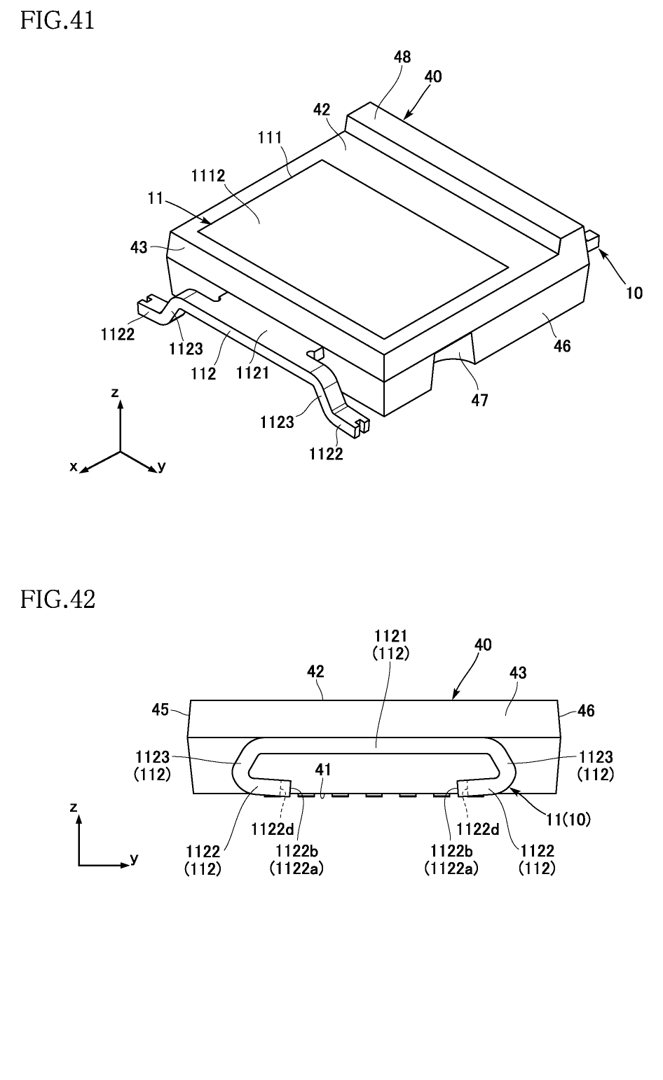

FIG. 41 shows a semiconductor device according to a fourth variation. The semiconductor device shown in FIG. 41 is different from the semiconductor device shown in FIGS. 39 and 40 in that the sealing resin 40 includes a protrusion 48 instead of the groove 49.

The protrusion 48 protrudes upward from the second resin surface 42 in the thickness direction z. The protrusion 48 extends from the fifth resin surface 45 to the sixth resin surface 46 along the second direction y. In the illustrated example, the protrusion 48 is located at the end of the sealing resin 40 on the second side in the first direction x, and is in contact with the fourth resin surface 44. The protrusion 48 of the sealing resin 40 can increase the creepage distance between the first lead reverse surface 1112 (the first lead 11) and each of the second terminal portions 122 (the second lead 12), the third terminal portion 132 (the third lead 13), and the fourth terminal portion 142 (the fourth lead 14). This makes it possible to improve the dielectric strength between the first lead 11 and each of the second lead 12, the third lead 13, and the fourth lead 14.

FIG. 42 shows a semiconductor device according to a fifth variation. The semiconductor device shown in FIGS. 42 is different from the semiconductor device A10 in the following respect. That is, the two first-terminal tip portions 1122 are bent inward relative to the two respective first-terminal intermediate portions 1123.

In the semiconductor device shown in FIG. 42, the two first-terminal tip portions 1122 extend inward from the two respective first-terminal intermediate portions 1123 in the second direction y. Thus, the two first-terminal tip portions 1122 extend toward each other. The first tip surfaces 1122a of the two first-terminal tip portions 1122 face each other.

As can be understood from the present variation, in the semiconductor device according to the present disclosure, the direction in which the first-terminal tip portions 1122 extend relative to the first-terminal intermediate portions 1123 is not particularly limited.

In the first to fifth embodiments and the variations described above, the first-terminal tip portions 1122 are formed with the recessed surfaces 1122d. In addition to or instead of this example, a recessed surface may be formed in at least one of the second-terminal tip portions 1222, the tip portion 1322, or the tip portion 1422. In other words, the shape of at least one of the second-terminal tip portions 1222, the tip portion 1322, or the tip portion 1422 may be formed to coincide with the shape of each first-terminal tip portion 1122.

The semiconductor device according to the present disclosure is not limited to the above embodiments. Various design changes can be made to the specific configurations of the elements of the semiconductor device according to the present disclosure. The present disclosure includes the embodiments described in the following clauses.

### Clause 1.

A semiconductor device comprising:

a semiconductor element;

a first lead including a die pad portion and a first terminal portion, the die pad portion including a first lead obverse surface facing a first side in a thickness direction and having the semiconductor element mounted thereon, and a first lead reverse surface facing a second side in the thickness direction; and

a sealing resin including a first resin surface facing the first side in the thickness direction, a second resin surface facing the second side in the thickness direction, and a third resin surface facing a first side in a first direction perpendicular to the thickness direction, the sealing resin covering the semiconductor element and a part of the die pad portion,

wherein the first lead includes a metal layer covering a part of the first terminal portion,

the first lead reverse surface is exposed from the second resin surface,

the first terminal portion includes a first-terminal base portion and at least one first-terminal tip portion,

the first-terminal base portion passes through the third resin surface, and is spaced apart from the first resin surface in the thickness direction,

the at least one first-terminal tip portion is offset to the first side in the thickness direction relative to the first-terminal base portion, and is used for mounting,

the at least one first-terminal tip portion includes a first tip surface and a recessed surface connected to the first tip surface,

the first tip surface is exposed from the metal layer, and

the recessed surface is covered with the metal layer.

### Clause 2.

The semiconductor device according to clause 1, wherein the first tip surface includes two exposed areas spaced apart from each other, and

the recessed surface is flanked by the two exposed areas.

### Clause 3.

The semiconductor device according to clause 2, wherein the two exposed areas are spaced apart from each other in the first direction.

### Clause 4.

The semiconductor device according to clause 3, wherein the first tip surface includes a connecting area that connects the two exposed areas, and that is flush with the two exposed areas,

and the connecting area is exposed from the metal layer.

### Clause 5.

The semiconductor device according to clause 4, wherein the at least one first-terminal tip portion includes a first mounting surface that faces the first side in the thickness direction, and that is connected to the first tip surface, and

the recessed surface is connected to the first mounting surface.

### Clause 6.

The semiconductor device according to any one of clauses 3 to 5, wherein the first terminal portion includes at least one first-terminal intermediate portion each interposed between the first-terminal base portion and one of the at least one first-terminal tip portion.

### Clause 7.

The semiconductor device according to clause 6, wherein the two exposed areas are located outward relative to a corresponding one of the at least one first-terminal intermediate portion, as viewed in a direction from the first tip surface to the corresponding first-terminal intermediate portion.

### Clause 8.

The semiconductor device according to clause 6 or 7, further comprising a second lead including a first pad portion covered with the sealing resin, and at least one second terminal portion exposed from the sealing resin,

the sealing resin includes a fourth resin surface facing a second side in the first direction, and

the at least one second terminal portion passes through the fourth resin surface.

### Clause 9.

The semiconductor device according to clause 8, wherein the at least one second terminal portion includes a second-terminal base portion, a second-terminal tip portion, and a second-terminal intermediate portion.

### Clause 10.

The semiconductor device according to clause 9, wherein the first-terminal intermediate portion has a first dimension,

the second-terminal intermediate portion has a second dimension,

the first dimension is along a direction perpendicular to both the thickness direction and a direction in which the first-terminal intermediate portion extends as viewed in the thickness direction,

the second dimension is along a direction perpendicular to both the thickness direction and a direction in which the second-terminal intermediate portion extends as viewed in the thickness direction, and

the first dimension is at least 0.5 times and at most twice the second dimension.

### Clause 11.

The semiconductor device according to any one of clauses 8 to 10, wherein the at least one second terminal portion includes a plurality of second terminal portions, and

the plurality of second terminal portions are connected to the first pad portion.

### Clause 12.

The semiconductor device according to any one of clauses 8 to 11, further comprising a third lead including a second pad portion covered with the sealing resin, and a third terminal portion exposed from the sealing resin, and

the third terminal portion passes through the fourth resin surface.

### Clause 13.

The semiconductor device according to any one of clauses 1 to 12, wherein the at least one first-terminal tip portion includes two first-terminal tip portions, and

the two first-terminal tip portions extend to opposite sides with respect to the first-terminal base portion in a second direction perpendicular to the thickness direction and the first direction.

### Clause 14.

The semiconductor device according to any one of clauses 1 to 13, wherein the first terminal portion is formed with depressions,

the first-terminal base portion includes a pair of base side surfaces facing away from each other in a second direction perpendicular to the thickness direction and the first direction, and

as viewed in the thickness direction, each of the depressions of the first terminal portion is recessed from one of the pair of base side surfaces or from one of a pair of extending surfaces respectively connected to the pair of base side surfaces.

### Clause 15.

The semiconductor device according to clause 14, wherein the depressions are formed in the pair of base side surfaces.

### Clause 16.

The semiconductor device according to clause 15, wherein as viewed in the thickness direction, each of the depressions is located at a side of one of the pair of base side surfaces, the side being connected to one of the pair of extending surfaces.

### Clause 17.

A vehicle comprising:

a drive source;

a storage battery that stores power supplied to the drive source; and

an on-board charger that converts power inputted from an external source, and that supplies the power to the storage battery,

wherein the on-board charger includes the semiconductor device according to any one of clauses 1 to 16.

### REFERENCE NUMERALS

A10, A20, A30, A40, A50, A51: Semiconductor device 10: Conductive member 11: First lead 12: Second lead 13: Third lead 14: Fourth lead 20: Semiconductor element

29: Bonding layer 31, 32, 33: Connecting member 40: Sealing resin 41: First resin surface 42: Second resin surface 43: Third resin surface 44: Fourth resin surface 45: Fifth resin surface 46: Sixth resin surface 47: Recess 48: Protrusion 49: Groove

80: Lead frame 81: Frame body 82: Notch 91: Heat sink 92: Circuit board 95: On-board charger 96: Storage battery 97: Drive system 110: Metal layer 111: Die pad portion 112: First terminal portion 113: Depression 114: Recess 120: Metal layer 121: Pad portion 122: Second terminal portion 130: Metal layer 131: Pad portion 132: Third terminal portion 140: Metal layer 141: Pad portion 142: Fourth terminal portion 201: First electrode 202: Second electrode 203: Third electrode 205: Semiconductor layer 919: Sheet member 921: Solder 971: Inverter 972: Drive source 1111: First lead obverse surface 1112: First lead reverse surface 1113: First lead side surface 1114: First intermediate surface 1120: Through-hole 1121: First-terminal base portion 1121a: Base side surface 1122: First-terminal tip portion

1122a: First tip surface 1122b: Exposed area 1122c: Connecting area 1122d: Recessed surface 1123: First-terminal intermediate portion 1123a: Extending surface

1211: Second lead obverse surface 1212: Second lead reverse surface 1221: Second-terminal base portion 1222: Second-terminal tip portion 1223: Second-terminal intermediate portion 1311: Third lead obverse surface 1312: Third lead reverse surface 1321: Base portion 1322: Tip portion 1323: Intermediate portion 1411: Fourth lead obverse surface 1412: Fourth lead reverse surface 1421: Base portion 1422: Tip portion 1423: Intermediate portion CL: Cut line V: Vehicle

1. A semiconductor device comprising:
a semiconductor element;
a first lead including a die pad portion and a first terminal portion, the die pad portion including a first lead obverse surface facing a first side in a thickness direction and having the semiconductor element mounted thereon, and a first lead reverse surface facing a second side in the thickness direction; and
a sealing resin including a first resin surface facing the first side in the thickness direction, a second resin surface facing the second side in the thickness direction, and a third resin surface facing a first side in a first direction perpendicular to the thickness direction, the sealing resin covering the semiconductor element and a part of the die pad portion,
wherein the first lead includes a metal layer covering a part of the first terminal portion,
the first lead reverse surface is exposed from the second resin surface,
the first terminal portion includes a first-terminal base portion and at least one first-terminal tip portion,
the first-terminal base portion passes through the third resin surface, and is spaced apart from the first resin surface in the thickness direction,
the at least one first-terminal tip portion is offset to the first side in the thickness direction relative to the first-terminal base portion, and is used for mounting,
the at least one first-terminal tip portion includes a first tip surface and a recessed surface connected to the first tip surface,
the first tip surface is exposed from the metal layer, and
the recessed surface is covered with the metal layer.

2. The semiconductor device according to claim 1, wherein the first tip surface includes two exposed areas spaced apart from each other, and
the recessed surface is flanked by the two exposed areas.

3. The semiconductor device according to claim 2, wherein the two exposed areas are spaced apart from each other in the first direction.

4. The semiconductor device according to claim 3, wherein the first tip surface includes a connecting area that connects the two exposed areas, and that is flush with the two exposed areas, and
the connecting area is exposed from the metal layer.

5. The semiconductor device according to claim 4, wherein the at least one first-terminal tip portion includes a first mounting surface that faces the first side in the thickness direction, and that is connected to the first tip surface, and
the recessed surface is connected to the first mounting surface.

6. The semiconductor device according to claim 3, wherein the first terminal portion includes at least one first-terminal intermediate portion each interposed between the first-terminal base portion and one of the at least one first-terminal tip portion.

7. The semiconductor device according to claim 6, wherein the two exposed areas are located outward relative to a corresponding one of the at least one first-terminal intermediate portion, as viewed in a direction from the first tip surface to the corresponding first-terminal intermediate portion.

8. The semiconductor device according to claim 6, further comprising a second lead including a first pad portion covered with the sealing resin, and at least one second terminal portion exposed from the sealing resin,
the sealing resin includes a fourth resin surface facing a second side in the first direction, and
the at least one second terminal portion passes through the fourth resin surface.

9. The semiconductor device according to claim 8, wherein the at least one second terminal portion includes a second-terminal base portion, a second-terminal tip portion, and a second-terminal intermediate portion.

10. The semiconductor device according to claim 9, wherein the first-terminal intermediate portion has a first dimension,
the second-terminal intermediate portion has a second dimension,
the first dimension is along a direction perpendicular to both the thickness direction and a direction in which the first-terminal intermediate portion extends as viewed in the thickness direction,
the second dimension is along a direction perpendicular to both the thickness direction and a direction in which the second-terminal intermediate portion extends as viewed in the thickness direction, and
the first dimension is at least 0.5 times and at most twice the second dimension.

11. The semiconductor device according to claim 8, wherein the at least one second terminal portion includes a plurality of second terminal portions, and
the plurality of second terminal portions are connected to the first pad portion.

12. The semiconductor device according to claim 8, further comprising a third lead including a second pad portion covered with the sealing resin, and a third terminal portion exposed from the sealing resin, and
the third terminal portion passes through the fourth resin surface.

13. The semiconductor device according to claim 1, wherein the at least one first-terminal tip portion includes two first-terminal tip portions, and
the two first-terminal tip portions extend to opposite sides with respect to the first-terminal base portion in a second direction perpendicular to the thickness direction and the first direction.

14. The semiconductor device according to claim 1, wherein the first terminal portion is formed with depressions,
the first-terminal base portion includes a pair of base side surfaces facing away from each other in a second direction perpendicular to the thickness direction and the first direction, and
as viewed in the thickness direction, each of the depressions of the first terminal portion is recessed from one of the pair of base side surfaces or from one of a pair of extending surfaces respectively connected to the pair of base side surfaces.

15. The semiconductor device according to claim 14, wherein the depressions are formed in the pair of base side surfaces.

16. The semiconductor device according to claim 15, wherein as viewed in the thickness direction, each of the depressions is located at a side of one of the pair of base side surfaces, the side being connected to one of the pair of extending surfaces.

17. A vehicle comprising:
a drive source;
a storage battery that stores power supplied to the drive source; and
an on-board charger that converts power inputted from an external source, and that supplies the power to the storage battery,
wherein the on-board charger includes the semiconductor device according to claim 1.
